(19) United States
(12) Patent Application Publication
(10) Pub. No.: US 2026/0239835 A1
(43) Pub. Date: Aug. 13, 2026

(54) ELECTRONIC DEVICE

(71) Applicant: Samsung Display Co., Ltd., Yongin-si (KR)

(72) Inventors: Sukyo JUNG, Yongin-si (KR); Daehyun KIM, Yongin-si (KR); Minjoo KIM, Yongin-si (KR); Jeonghun BANG, Yongin-si (KR); Minki YANG, Yongin-si (KR); Jaewon CHO, Yongin-si (KR); Changkyu JIN, Yongin-si (KR)

(73) Assignee: Samsung Display Co., Ltd., Yongin-si (KR)

(21) Appl. No.: 19/349,582

(22) Filed: Oct. 3, 2025

(30) Foreign Application Priority Data
Feb. 13, 2025 (KR) 10-2025-0018887

(51) Int. Cl. H10K 59/131; H10K 102/00

(52) U.S. Cl. CPC H10K 59/131; H10K 2102/311

(57) ABSTRACT

Provided is an electronic device. The display panel includes a first display part, a second display part, and a bending part. The first display part includes a first active area and a first peripheral area surrounding the first active area, and the second display part includes a second active area and a second peripheral area. The display panel includes first pixels in the first active area, second pixels in the second active area, a (1-1)-th power line in the first peripheral area and connected to the first pixels, and a (1-2)-th power line in the first peripheral area, the bending part, and the second peripheral area and connected to the second pixels.

### CROSS-REFERENCE TO RELATED APPLICATIONS

This U.S. non-provisional patent application claims priority under 35 U.S.C. § 119 of Korean Patent Application No. 10-2025-0018887, Feb. 13, 2025, the entire contents of which are hereby incorporated by reference.

### BACKGROUND

Some example embodiments relate to an electronic device, and more particularly, to an electronic device with reduced power consumption.

Generally, electronic apparatuses that provide a user with an image, such as smart phones, digital cameras, laptop computers, navigation units, and smart televisions, include an electronic device for displaying the image. The electronic device generates an image and provides the generated image to the user through a display screen.

The electronic device includes a plurality of pixels for generating an image and a plurality of lines connected to the pixels. The pixels receive driving signals through the lines and are driven accordingly.

Recently, foldable electronic devices have additionally included a display panel for displaying an image to the outside while folded; accordingly, a design is desired in which an internal panel and an external panel are driven separately during folding and unfolding.

### SUMMARY

Some example embodiments an electronic device in which a panel that displays an image to the outside in a folded state and/or a panel that displays an image in an unfolded state are connected to different power lines.

According to some example embodiments, an electronic device includes a processor configured to provide image data and a display brightness value; a display panel including a first display part including a folding area configured to fold about a folding axis and at least two non-folding areas spaced apart from each other with the folding area therebetween; a second display part spaced apart from the first display part; and a bending part configured to connect the first display part to the second display part and configured to bend about a bending axis so that a rear surface of the second display part faces a rear surface of the first display part; a panel driver configured to receive the image data and the display brightness value and to drive the display panel based on the image data and the display brightness value; and a housing configured to accommodate the display panel and the panel driver. The first display part includes a first active area and a first peripheral area surrounding the first active area, the second display part includes a second active area and a second peripheral area surrounding the second active area. The display panel includes: a base layer; first pixels on the first active area; second pixels on the second active area; a (1-1)-th power line on the first peripheral area and connected to the first pixels; and a (1-2)-th power line on the first peripheral area, the bending part, and the second peripheral area and connected to the second pixels.

In some example embodiments, the (1-1)-th power line may be relatively closer to the first active area than the (1-2)-th power line.

In some example embodiments, each of the (1-1)-th power line and the (1-2)-th power line may include a first conductive layer and a second conductive layer on the first conductive layer and in contact with the first conductive layer.

In some example embodiments, the display panel may further include an encapsulation layer covering the first pixels and the second pixels, and the encapsulation layer may include a first inorganic layer, a second inorganic layer on the first inorganic layer, and an organic layer between the first and second inorganic layers.

In some example embodiments, the electronic device may further include at least one dam part defining a boundary of the organic layer on the first and second peripheral areas. The at least one dam part may include sequentially laminated dam patterns, each of which includes an organic material.

In some example embodiments, the (1-1)-th power line and the (1-2)-th power line may be spaced apart from each other with the at least one dam part therebetween and on the first peripheral area.

In some example embodiments, the (1-1)-th power line and the (1-2)-th power line may be on different layers, respectively.

In some example embodiments, the display panel may include a (2-1)-th power line including (1-1)-th lines disposed on the first active area, each of which extends in a first direction and arranged in a second direction crossing the first direction, and (1-2)-th lines each of which extends in the second direction and arranged in the first direction; and a (2-2)-th power line including (2-1)-th lines on the second active area, each of which extends in the first direction and arranged in the second direction, and (2-2)-th lines each of which extends in the second direction and arranged in the first direction, and the display panel may further include a voltage generator configured to individually supply power to the (1-1)-th power line, the (1-2)-th power line, the (2-1)-th power line, and the (2-2)-th power line.

In some example embodiments, the (1-2)-th lines may be connected to the voltage generator and extend from the voltage generator to the first active area through the first peripheral area.

In some example embodiments, the (2-2)-th lines may be connected to the voltage generator and extend from the voltage generator to the second active area through the first peripheral area, the first active area, the bending part, and the second peripheral area.

In some example embodiments, each of the (2-2)-th lines may be between adjacent (1-2)-th lines along the second direction within the first active area, and the (2-2)-th lines may not overlap the (1-2)-th lines.

In some example embodiments, each of the (2-2)-th lines may intersect the (1-1)-th lines within the first active area.

In some example embodiments, the (1-2)-th lines may be on the (1-1)-th lines, the (2-2)-thlines may be between the (2-1)-th lines, the (1-1)-th lines and the (2-1)-th lines may be on the same layer, and the (1-2)-th lines and the (2-2)-th lines may be on the same layer.

In some example embodiments, the (1-1)-th lines may be on the (1-2)-th lines, the (2-1)-th lines may be between the (2-2)-th lines, the (1-1)-th lines may be on the same layer as the (2-1)-th lines, and the (1-2)-th lines may be on the same layer as the (2-2)-th lines.

In some example embodiments, the (2-2)-th power line may further include sub-lines on the first active area and arranged in the first direction, and each of which extends in the second direction. The sub-lines may be on the same layer as the (1-1)-th lines.

In some example embodiments, the sub-lines may intersect the (1-2)-th lines and the (2-2)-th lines and are spaced apart from the (1-1)-th lines.

In some example embodiments, each of the (1-1)-th lines may be connected to at least one transistor in the first pixels within the first active area, and each of the (2-1)-th lines may be connected to at least one transistor provided in the second pixels within the second active area.

In some example embodiments, the (1-1)-th power line may be configured to apply a voltage lower than (e.g., lower in absolute value than) that of the (2-1)-th power line to the first pixels, and the (2-1)-th power line may be configured to apply a voltage lower than (e.g., lower in absolute value than) that of the (2-2)-th power line to the second pixels.

In some example embodiments, in a first mode in which the folding area is folded, the voltage generator may be configured to supply power only to the (1-2)-th and (2-2)-th power lines so as to drive the first pixels, and in a second mode in which the folding area is unfolded, the voltage generator may be configured to supply power only to the (1-1)-th and (2-1)-th power lines so as to drive the second pixels.

In some example embodiments, in the first mode, the first active area overlapping the non-folding areas may be in-folded to face each other.

### BRIEF DESCRIPTION OF THE FIGURES

The accompanying drawings are included to provide a further understanding of the inventive concept, and are incorporated in and constitute a part of this specification. The drawings illustrate embodiments of inventive concepts and, together with the description, serve to explain principles of inventive concepts. In the drawings:

FIG. 1A is a block diagram of an electronic device according to some example embodiments of inventive concepts;

FIG. 1B is schematic diagrams of electronic devices according to various embodiments of inventive concepts;

FIGS. 2A to 2F are perspective views showing an electronic device according to some example embodiments of inventive concepts;

FIG. 3A is an exploded perspective view showing the electronic device according to some example embodiments of inventive concepts;

FIG. 3B is a plan view of a display panel in a first mode of the electronic device according to some example embodiments of inventive concepts;

FIG. 3C is a plan view of the display panel in a second mode of the electronic device according to some example embodiments of inventive concepts;

FIG. 4 is a cross-sectional view of a portion of a display module according to some example embodiments of inventive concepts;

FIG. 5A is a plan view of the display panel according to some example embodiments of inventive concepts;

FIG. 5B is an equivalent circuit diagram of a pixel according to some example embodiments of inventive concepts;

FIG. 6 is a cross-sectional view of the display panel according to some example embodiments of inventive concepts;

FIG. 7 is a plan view of a display panel according to some example embodiments of inventive concepts;

FIG. 8A is a cross-sectional view taken along line I-I′ of FIG. 7 according to some example embodiments of inventive concepts;

FIG. 8B is a cross-sectional view taken along line I-I′ of FIG. 7 according to some example embodiments of inventive concepts;

FIG. 9 is a plan view of a display panel according to some example embodiments of inventive concepts;

FIG. 10A is a cross-sectional view taken along line II-II′ of FIG. 9 according to some example embodiments of inventive concepts;

FIG. 10B is a cross-sectional view taken along line III-III′ of FIG. 9 according to some example embodiments of inventive concepts;

FIG. 11 is a cross-sectional view of a display panel according to some example embodiments of inventive concepts;

FIG. 12 is a cross-sectional view of a display panel according to some example embodiments of inventive concepts; and

FIG. 13 is a plan view of the display panel according to some example embodiments of inventive concepts.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. The thickness and/or the ratio and/or the dimension of the element may be exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

The terminology used herein is for the purpose of describing particular embodiments only and is not intended to be limiting of the invention. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

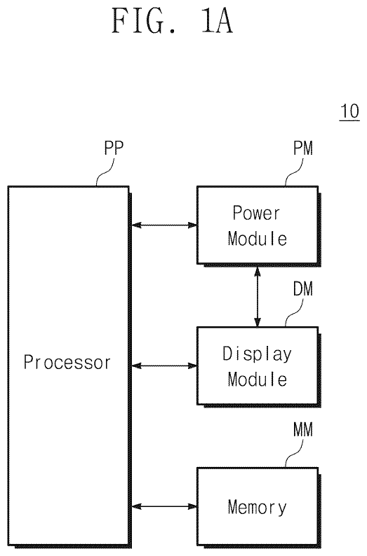

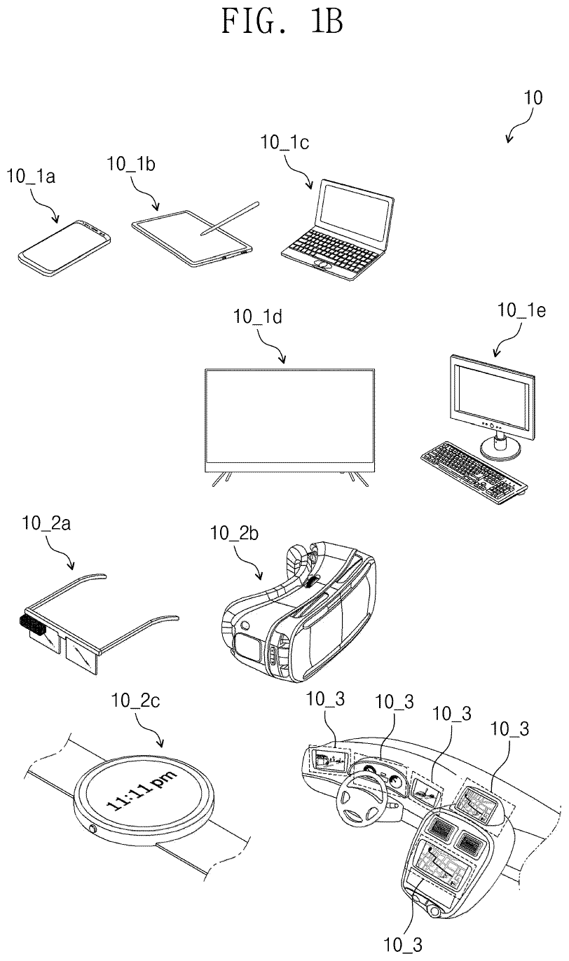

Hereinafter, some example embodiments of inventive concepts are described with reference to the drawings. FIG. 1A is a block diagram of an electronic device according to some example embodiments of inventive concepts. FIG. 1B is schematic diagrams of electronic devices according to various embodiments of inventive concepts.

Referring to FIG. 1A, an electronic device 10 according to some example embodiments may include a display module DM, a processor PP, a memory MM, and a power module PM.

The processor PP may include at least one of a central processing unit CPU, an application processor AP, a graphic processing unit GPU, a communication processor CP, an image signal processor ISP, or a controller member.

The memory MM may store data information necessary for and/or useful for the operation of the processor PP and/or the display module DM. When the processor PP executes an application stored in the memory MM, an image data signal and/or an input control signal may be transmitted to the display module DM, and the display module DM may process the received signal to output image information through a display screen.

The power module PM may include a power supply module, such as one or more of a power adapter or a battery device, and a power conversion module that converts the power supplied by the power supply module to generate the power required for the operation of the electronic device 10.

At least one of the components of the above-described electronic device 10 may be included in the display device according to some example embodiments. Alternatively or additionally, a part of the individual modules functionally included in a single module may be included in the display device, and the other part may be provided separately from the display device. For example, the display device may include the display module DM, and the processor PP, the memory MM, and the power module PM may be provided in the type of another component within the electronic device 10 rather than in the display device.

Referring to FIG. 1B, various electronic devices to which the display device according to some example embodiments is applied may include image display electronic devices such as one or more of a smartphone 10_1a, a tablet PC 10_1b, a laptop 10_1c, a TV 10_1d, and a desktop monitor 10_1e; wearable electronic devices including a display module, such as smart glasses 10_2a, a head-mounted display 10_2b, and a smart watch 10_2c; and vehicle electronic devices 10_3 including a display module, such as a CID (Center Information Display), a room mirror display, or a cluster, a center fascia, or a dashboard of a vehicle. Hereinafter, features applicable to inventive concepts may be applied to all of the above-described electronic devices, and in particular, an example will be given in which the features are applied to a foldable electronic device ED or ED-a that may correspond to the above-described smartphone 10_1a; example embodiments are not limited thereto.

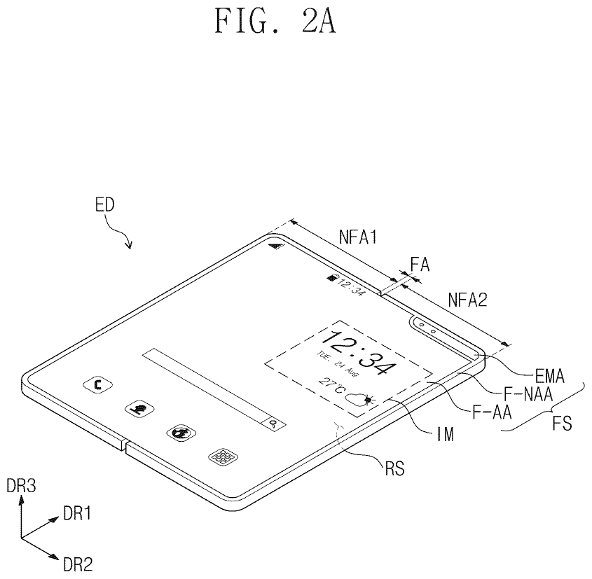

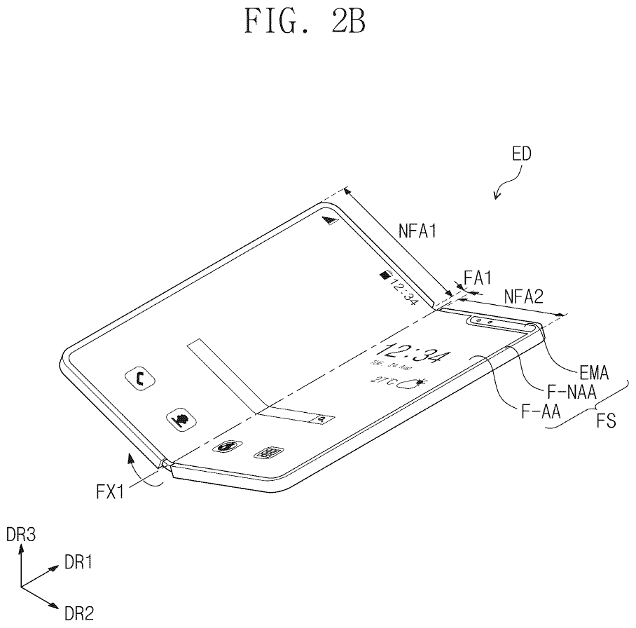

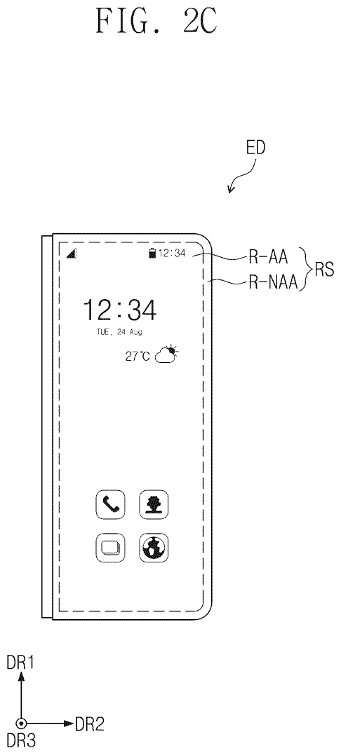

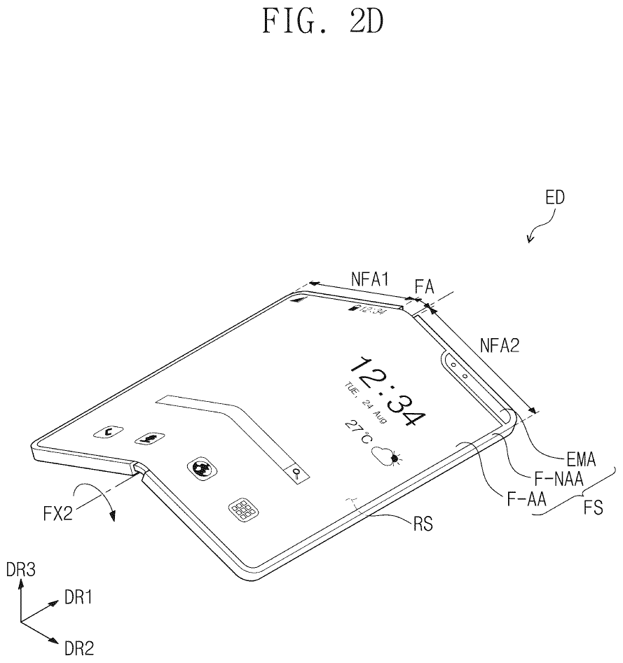

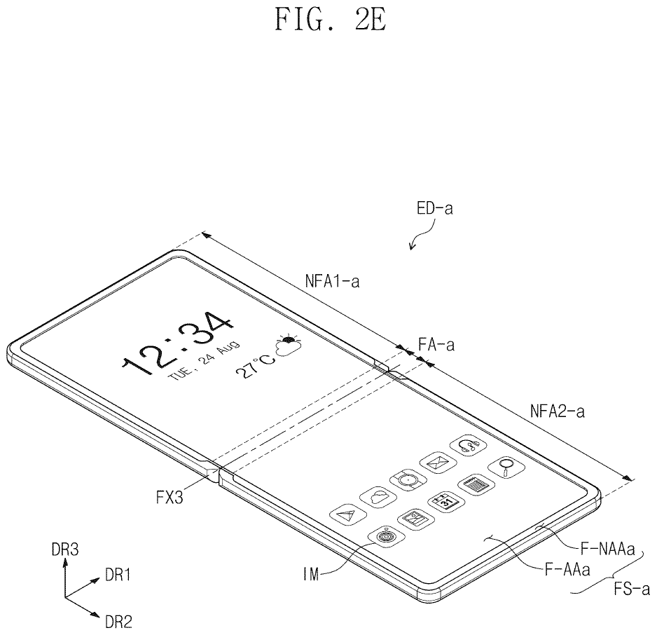

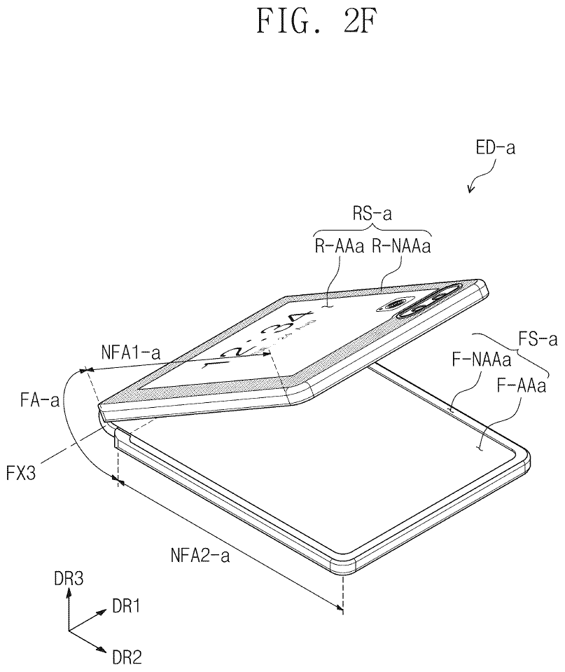

FIGS. 2A to 2F are perspective views showing an electronic device according to some example embodiments of inventive concepts.

FIG. 2A is a perspective view of an electronic device ED according to some example embodiments. The electronic device ED according to some example embodiments may be or may include (or be included in) a device that is activated in response to an electrical signal. For example, the electronic device ED may be, include, or be included in one or more of a mobile phone, a tablet PC, a vehicle navigation unit, a game console, or a wearable device, but example embodiments are not limited thereto. FIGS. 2A to 2F illustrate an example of foldable electronic devices ED and ED-a. The foldable electronic devices ED and ED-a according to some example embodiments may be the above-described smartphone 10_1a (e.g., a mobile phone).

The electronic device ED may include a first display surface FS defined by a first direction DR1 and a second direction DR2 intersecting the first direction DR1. The electronic device ED may provide an image IM through the first display surface FS. The image IM may be provided to a user; example embodiments are not limited thereto. The electronic device ED may display the image IM in a third direction DR3 through the first display surface FS, which is parallel to each of the first direction DR1 and the second direction DR2.

As used herein, the first direction DR1 and the second direction DR2 may be perpendicular to each other. The third direction DR3 may be a normal direction with respect to a plane defined by the first direction DR1 and the second direction DR2. A thickness direction of the electronic device ED may be a direction parallel to the third direction DR3. A front surface (or top surface) and a rear surface (or bottom surface) may oppose each other in the third direction DR3, and normal directions of the front surface (or top surface) and the rear surface (or bottom surface) may be parallel to the third direction DR3.

The front surface (or top surface) may refer to a surface close to the first display surface FS, and the rear surface (or bottom surface) may refer to a surface spaced apart from the first display surface FS. In addition, the rear surface (or bottom surface) may refer to a surface close to a second display surface RS, which will be described later. An upper side (or upper portion) may refer to a direction approaching the first display surface FS, and a lower side (or lower portion) may refer to a direction away from the first display surface FS.

A cross-section of a component may refer to a surface parallel to the thickness direction, e.g., the third direction DR3, and a plane may refer to a surface perpendicular to the thickness direction, e.g., the third direction DR3. The plane may refer to a surface defined by the first direction DR1 and the second direction DR2.

The electronic device ED may detect an external input applied from outside. The external input may include one or more of various types of inputs provided from outside the electronic device ED. For example, the external input may include contact by a part of the body of a user, such as a hand, and may additionally or alternatively include an external input that is applied in proximity to, or at a specific distance from (e.g., a dynamically determined or predetermined distance from), the electronic device ED (e.g., hovering). Alternatively or additionally, various types of input, such as one or more of force, pressure, temperature, and light, may correspond to the external input.

The electronic device ED may include the first display surface FS and the second display surface RS. The first display surface FS may include an active area F-AA, a peripheral area F-NAA, and an electronic module area EMA. The second display surface RS may be defined as a surface which faces at least a portion of the first display surface FS. Accordingly, the second display surface RS may be defined as a portion of a rear surface of the electronic device ED when the electronic device ED is in an unfolded state.

A first active area F-AA may be or may include (or be included in) an area that is activated in response to an electrical signal. The first active area F-AA may be or may include (or be included in) an area in which the image IM is displayed, and various types of external inputs may be detected.

A first non-active area F-NAA may be or may include (or be included in) an area in which the image IM is not displayed. The first non-active area F-NAA may be adjacent to the first active area F-AA. The first non-active area F-NAA may have a color such as a dynamically determine color, or, alternatively, a predetermined color. The first peripheral area F-NAA may surround the first active area F-AA. Accordingly, the shape of the first active area F-AA may be substantially defined by the first peripheral area F-NAA. However, this is merely an example, and the first peripheral area F-NAA may be disposed adjacent to only one side of the first active area F-AA or omitted.

Various electronic modules may be arranged in the electronic module region EMA. For example, the electronic module may include at least one of a camera, a speaker, a light detection sensor, or a heat detection sensor. The electronic module region EMA may sense an external object received through the first and second display surfaces FS and RS or provide a sound signal, such as voice, to the outside through the first and second display surfaces FS and RS. The electronic modules may include a plurality of components and are not limited to one specific embodiment.

The electronic module area EMA may be surrounded by the first non-active area F-NAA. However, this is merely an example and is not limited to any one example embodiment. For example, the electronic module area EMA may be surrounded by the first active area F-AA and the first non-active area F-NAA, and the electronic module area EMA may be disposed within the first active area F-AA. In this case, a hole that penetrates through the overlapping region with the electronic module area EMA may be defined.

The electronic device ED according to some example embodiments may be divided into at least one folding area FA and a plurality of non-folding areas NFA1 and NFA2 extended from the folding area FA. For example, a first non-folding area NFA1, a folding area FA, and a second non-folding area NFA2 may be defined along the second direction DR2; however, example embodiments are not limited thereto, and the first non-folding area NFA1, the folding area FA, and the second non-folding area may be defined along the first direction DR1.

The electronic device ED may be divided into the first non-folding area NFA1 and the second non-folding area NFA2, which are spaced apart from each other in the second direction DR2 with the folding area FA therebetween. For example, the first non-folding area NFA1 may be disposed at one side of the folding area FA in the second direction DR2, and the second non-folding area NFA2 may be disposed at the other side of the folding area FA in the second direction DR2.

Referring to FIG. 2B, the electronic device ED according to some example embodiments may be foldable about a first folding axis FX1 extending in the first direction DR1. In some example embodiments, the first folding axis FX1 may divide the electronic device ED in half; however, example embodiments are not limited thereto. In a folded state of the electronic device ED, the folding area FA may have a curvature such as but not limited to a dynamically determined curvature, or alternatively, a predetermined curvature and radius of curvature. The electronic device ED may be folded about the first folding axis FX1 such that the first non-folding area NFA1 and the second non-folding area NFA2 face each other and may be transformed into an in-folding state in which the first display surface FS is not exposed to the outside. As described herein, a state in which the electronic device ED is being folded or is folded may be defined as a “first mode.” A state in which the electronic device ED is being unfolded or is unfolded may be defined as a “second mode.” Accordingly, when the first mode is performed, the first active area F-AA, which overlaps the first non-folding area NFA1 and the second non-folding area NFA2, may face each other.

Referring to FIG. 2C, in the in-folded state of the electronic device ED according to some example embodiments, the second display surface RS may be visible to the user. At this point, the second display surface RS may include a second active area R-AA for displaying an image. The second active area R-AA may be or may include (or be included in) an area that is activated in response to an electrical signal. The second active area R-AA may be or may include (or be included in) an area in which an image is displayed, and various types of external inputs may be detected.

The second display surface RS may include a second non-active area R-NAA. The second non-active area R-NAA may be adjacent to the second active area R-AA. The second non-active area R-NAA may have a color, such as but not limited to a dynamically determined color (or, alternatively, a predetermined color. The second non-active area R-NAA may surround the second active area R-AA. Although not shown, the electronic device ED may further include an electronic module area in which an electronic module including various components is disposed on the second display surface RS, and inventive concepts is not limited to any one example embodiment.

According to inventive concepts, in the first mode in which the electronic device ED is unfolded, only the pixels disposed in the first active area F-AA included in the electronic device ED may be driven, and in the second mode in which the electronic device ED is folded, only the pixels disposed in the second active area R-AA may be driven. Accordingly, in the unfolded state of the electronic device ED, the pixels disposed in the second active area R-AA may be completely turned off because power is not supplied thereto, and in the folded state of the electronic device ED, the pixels disposed in the first active area F-AA may be completely turned off because power is not supplied thereto. Therefore, the electronic device ED may reduce unintended power consumption. The related explanation will be described later.

According to some example embodiments, in a state in which the electronic device ED is in-folded, a distance between the first non-folding area NFA1 and the second non-folding area NFA2 may be smaller than a radius of a circle defined by a radius of curvature of the folding area FA. At this time, the folding area FA may be folded in a dumbbell shape, and the distance between the first non-folding area NFA1 and the second non-folding area NFA2 may become smaller. Accordingly, a slimmer electronic device ED in the folded state may be provided.

Referring to FIG. 2D, the electronic device ED according to some example embodiments may be foldable about a second folding axis FX2 extending in the first direction DR1. The electronic device ED may be folded about the second folding axis FX2 and may be changed into an out-folding state in which the first display surface FS is exposed to the outside. In some example embodiments, the electronic device ED may be provided to repeatedly perform in-folding and out-folding operations from an unfolding operation, but is not limited thereto. In some example embodiments, the first folding axis FX1 and the second folding axis FX2 may correspond to each other in a plane defined by the first direction DR1 and the second direction DR2; however, example embodiments are not limited thereto.

Although FIGS. 2A to 2D illustrate an example of folding based on a single folding axis (FX1 or FX2), the number of folding axes and the number of non-folding areas corresponding thereto are not limited thereto. For example, the electronic device ED may be folded based on a plurality of folding axes such that a portion of each of the first display surface FS and the second display surface RS may face each other. Alternatively or additionally, although the first and second folding axes FX1 and FX2 are illustrated as being parallel to a long side of the electronic device ED, example embodiments are not limited thereto, and the first and second folding axes FX1 and FX2 may be parallel to a short side of the electronic device ED.

FIG. 2E is a perspective view showing a display device according to some example embodiments. FIG. 2F is a perspective view showing the display device according to some example embodiments.

FIGS. 2E and 2F are perspective views showing an electronic device ED-a according to some example embodiment of inventive concepts. FIG. 2E is a perspective view showing an unfolded state of the electronic device ED-a. FIG. 2F is a perspective view showing a folding operation of the electronic device ED-a. FIG. 2F is a perspective view showing an operation in a second mode of the electronic device ED-a illustrated in FIG. 2E.

Referring to FIG. 2E, the electronic device ED-a may be foldable about a third folding axis FX3 extending in the first direction DR1. An extending direction of the third folding axis FX3 may extend along the first direction DR1, which is parallel to an extending direction of a short side of the electronic device ED-a.

The electronic device ED-a may include a folding area FA-a, a first non-folding area NFA1-a, and a second non-folding area NFA2-a, which are arranged along the second direction DR2. The first non-folding area NFA1-a and the second non-folding area NFA2-a may be spaced apart from each other with the folding area FA-a therebetween.

The folding area FA-a may be an area that is folded about the third folding axis FX3. In a folded state of the electronic device ED-a, the folding area FA-a may have a predetermined curvature and radius of curvature. The first non-folding area NFA1-a and the second non-folding area NFA2-a may face each other, and the electronic device ED-a may be in-folded such that a display surface FS is not exposed to the outside.

Referring to FIG. 2E, in some example embodiments, in an unfolded state (e.g., a non-folded state) of the electronic device ED-a, a first display surface FS-a may be visible to the user. As described with reference to FIGS. 2A to 2D, a first display surface FS-a of the electronic device ED-a may include a first active area F-AAa and a first non-active area F-NAAa. The first active area F-AAa may be an area in which an image IM is displayed and various types of external inputs may be detected in an unfolding state or an unfolded state.

Referring to FIG. 2F, in a state in which the electronic device ED-a is in-folded according to the first mode, a second display surface RS-a may be visible to the user. The second display surface RS-a may include a second active area R-AAa and a second non-active area R-NAAa. The second non-active area R-NAAa may have a color such as a dynamically determined color (or, alternatively, a predetermined color). The second non-active area R-NAAa may surround the second active area R-AAa. According to inventive concepts, when the first mode is performed, the first active area F-AAa, which overlaps the first non-folding area NFA1-a and the second non-folding area NFA2-a, may face each other.

According to some example embodiments, in an unfolded state of the electronic device ED-a, the pixels disposed in the second active area R-AAa may be completely turned off because power is not supplied, and in a folded state of the electronic device ED-a, the pixels disposed in the first active area F-AAa may be completely turned off because power is not supplied. Therefore, the electronic device ED may reduce unintended power consumption. The related explanation will be provided later.

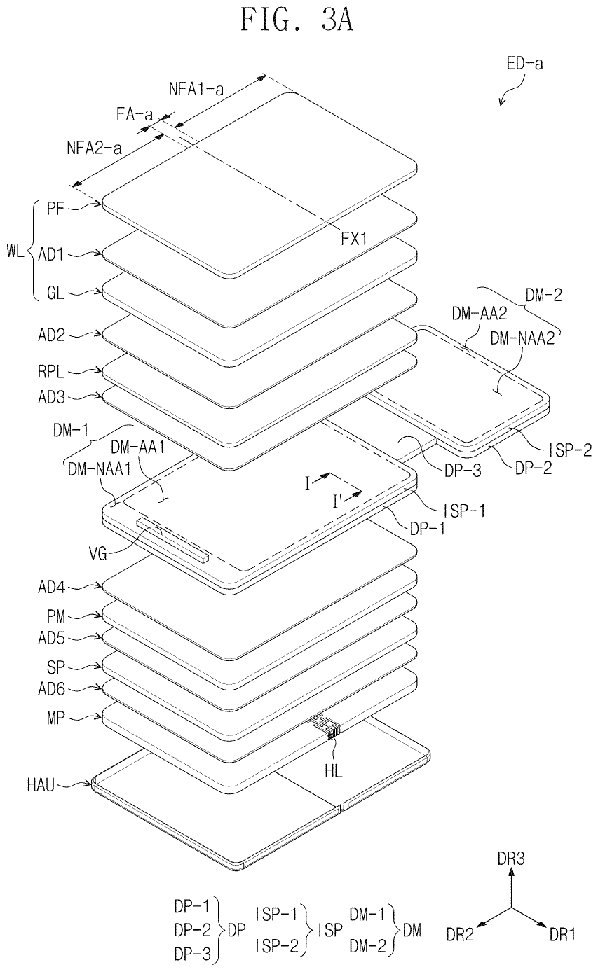

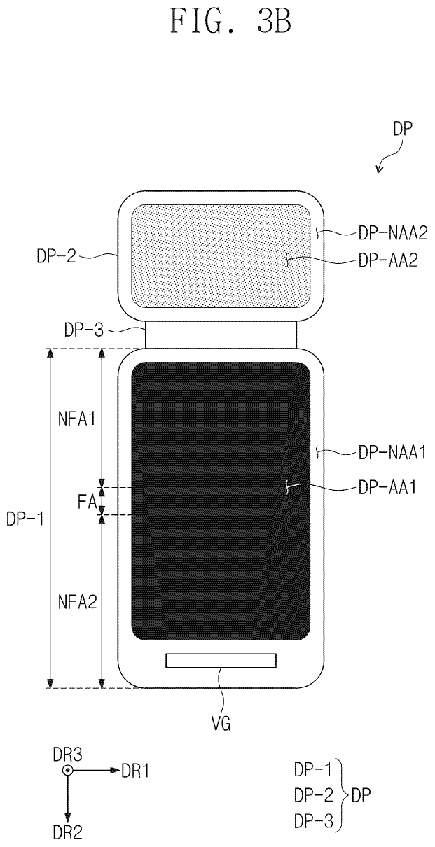

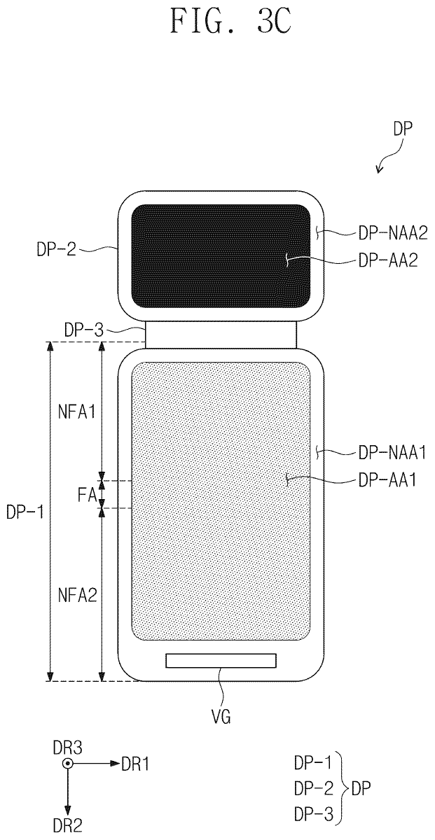

FIG. 3A is an exploded perspective view showing the electronic device according to some example embodiments of inventive concepts. FIG. 3A illustrates an exploded perspective view of the electronic device ED-a described with reference to FIGS. 2E and 2F.

Referring to FIG. 3A, the electronic device ED-a may include a window WL, a display module DM, an optical layer RPL, a lower film PM, a support plate SP, a lower plate MP, and a housing HAU.

The housing HAU may be coupled to the window WL to define the appearance of the electronic device ED-a. The housing HAU may include a material having relatively high rigidity. For example, the housing HAU may include a plurality of frames and/or support plates composed of glass, plastic, or metal. The housing HAU may provide an accommodation space, such as a predetermined accommodation space. The display module DM may be accommodated within the accommodation space and protected from, or at least partially protected from, an external impact.

According to some example embodiments, the housing HAU overlapping the folding area FA may further include a hinge structure for guiding a folding operation of the electronic device ED-a. Alternatively or additionally, the housing HAU may include a first portion overlapping the first non-folding area NFA1-a and a second portion overlapping the second non-folding area NFA2-a in order to guide the folding operation of the electronic device ED-a, and the first and second portions may be connected by a hinge structure. Alternatively or additionally, an opening may be defined in the first portion of the housing HAU such that a second display area DM-AA2 of the second display module DM-2 may be visible to the outside in a folded state of the electronic device Ed-a.

The display module DM may be disposed below the optical layer RPL. The display module DM may be activated by an electrical signal. The display module DM may be activated to display an image IM (see FIG. 2A) on a first active area F-AAa and a second active area R-AAa of the electronic device ED-a.

The display module DM according to inventive concepts may include a first display module DM-1 and a second display module DM-2. A display panel DP included in the display module DM may include a first display part DP-1, a second display part DP-2, and a bending part DP-3, and an input sensing layer ISP included in the display module DM may include a first sensing layer ISP-1 and a second sensing layer ISP2.

The first display part DP-1 and the second display part DP-2 may be connected through the bending part DP-3, and the first sensing layer ISP-1 and the second sensing layer ISP2 may be connected through the bending part DP-3. As described herein, the first display module DM-1 may include the first display part DP-1 and the first sensing layer ISP-1, and the second display module DM-2 may include the second display part DP-2 and the second sensing layer ISP2.

The first display module DM-1 may include a first display area DM-AA1 overlapping the first active area F-AAa of the electronic device ED-a described in FIG. 2E and a first non-display area DM-NAA1 overlapping the first non-active area F-NAAa. A voltage generator VG may be disposed in the first non-active area F-NAAa. The voltage generator VG may generate voltages required for or used for an operation of the display panel DP. For convenience of explanation, the voltage generator VG is illustrated as being mounted on the first non-active area F-NAAa, but the voltage generator VG may be provided separately from and spaced apart from the display panel DP, and is not limited to any one example embodiment.

The bending portion DP-3 may be bent about a bending axis extending in the first direction DR1 with respect to the second display part DP-2. In a bent state of the bending portion DP-3, a rear surface of the first display part DP-1 and a rear surface of the second display part DP-2 may face each other. The display module DM may be accommodated in the housing HAU in a bent state of the bending portion DP-3. At this time, the second display part DP-2 may be visible to a user through an opening defined in a second portion of the housing HAU.

Accordingly, in the bent state of the bending part DP-3, the second display module DM-2 may include a second display area DM-AA2 disposed in the second active area R-AAa of the electronic device ED-a described in FIG. 2E and a second non-display area DM-NAA2 overlapping the second non-active area R-NAAa. The second sensing layer ISP2 may be bent along with the second display part DP-2.

According to some example embodiments, in the bent state of the bending portion DP-3, a fourth adhesive layer AD4 to a lower plate MP, disposed below the first display part DP-1, may be disposed between the first display part DP-1 and the second display part DP-2.

The display areas DM-AA1 and DM-AA2 may be areas that are activated in response to an electrical signal. The non-display areas DM-NAA1 and DM-NAA2 may be areas disposed adjacent to at least one side of the display areas DM-AA1 and DM-AA2. Circuits and/or wirings for driving the display areas DM-AA1 and DM-AA2 may be disposed in the display areas DM-AA1 and DM-AA2.

An optical layer RPL may be disposed between the display module DM and the window WL. The optical layer RPL may be or may include an anti-reflection layer that reduces reflectance caused by external light incident from outside the display module DM. The optical layer RPL may be disposed on the display module DM through a continuous process. The optical layer RPL may include a polarizing plate and/or may include a color filter layer. For example, the optical layer RPL may include at least one of a retarder, a polarizer, a polarizing film, and a polarizing filter. Alternatively or additionally, the optical layer RPL may include a plurality of color filters arranged in a predetermined pattern and a black matrix adjacent to the color filters.

An image IM (FIG. 2A) generated from the display module DM may be provided to a user through the window WL. The window WL may include a polymer substrate and/or a glass substrate.

The window WL according to some example embodiments may include a protective layer PF and a base layer GL. The protective layer PF and the base layer GL may include an optically transparent insulating material. In some example embodiments, the base layer GL may include polyethylene terephthalate (PET). The protective layer PF may be disposed on the base layer GL. The protective layer PF may be a functional layer that protects a top surface of the base layer GL. The protective layer PF may include a polymer film. The protective layer PF may include a fingerprint-resistant coating, a hard coating, and an antistatic agent.

According to some example embodiments, a light blocking pattern may be disposed between a first adhesive layer AD1 and the protective layer PF. The light blocking pattern may be provided by printing or coating on a portion, which is adjacent to an edge, of a bottom surface of the protective layer PF. The light blocking pattern may include a light-absorbing material and is not limited to any particular one.

A lower film PM may protect a bottom portion of the display panel DP. The lower film PM may include a flexible plastic material. For example, the lower film PM may include polyethylene terephthalate.

A support plate SP may be disposed below the display panel DP. A portion of the support plate SP according to inventive concepts may be bent to absorb impact applied between components disposed on the support plate SP and the housing HAU. Alternatively or additionally, the support plate SP may prevent or reduce the likelihood of and/or the impact from foreign matter or the like from being introduced into the components disposed on the support plate SP.

A lower plate MP may be disposed below the support plate SP. The lower plate MP may include or define a plurality of holes HL that overlap the folding area FA-a and penetrate through the lower plate MP to facilitate a folding operation of the electronic device ED-a. The lower plate MP may include a metal. For example, the lower plate MP may include one of aluminum (Al) and molybdenum (Mo).

However, the lower plate MP is not limited thereto and may include a matrix containing a filler and fiber lines of a woven shape disposed in the matrix. The fiber lines may be arranged in a fabric shape in the matrix.

The fiber lines may include a reinforced fiber composite. The reinforced fiber composite may be one of carbon fiber-reinforced plastic (CFRP) and glass fiber-reinforced plastic (GFRP). A single strand of fiber included in one fiber line may have a diameter of about 3 μm or more and about 10 μm or less.

The matrix according to some example embodiments may include at least one of epoxy, polyester, polyamides, polycarbonates, polypropylene, polybutylene, and vinyl ester.

The matrix may include a filler. The filler may include at least one of silica, barium sulphate, sintered talc, barium titanate, titanium oxide, clay, alumina, mica, boehmite, zinc borate, or zinc stannate.

The electronic device ED-a according to some example embodiments may further include at least one of a cushion layer and a shielding layer. The cushion layer may prevent or reduce the likelihood of and/or impact from compression and plastic deformation of the lower plate MP due to external impact and force. The cushion layer may include an elastomer such as one or more of sponge, foam, or urethane resin. Alternatively or additionally, the cushion layer may be provided by including at least one of an acrylic-based polymer, a urethane-based polymer, a silicon-based polymer, and an imide-based polymer. The shielding layer may be or may include an electromagnetic shielding layer and/or a heat dissipation layer.

The electronic device ED-a according to some example embodiments may further include first to sixth adhesive layers AD1 to AD6. A first adhesive layer AD1 may be disposed between the base layer GL and the protective layer PF. A second adhesive layer AD2 may be disposed between the optical layer RPL and the base layer GL. A third adhesive layer AD3 may be disposed between the display module DM and the optical layer RPL. A fourth adhesive layer AD4 may be disposed between the lower film PM and the display module DM. A fifth adhesive layer AD5 may be disposed between the support plate SP and the lower film PM. A sixth adhesive layer AD6 may be disposed between the lower plate MP and the support plate SP. According to some example embodiments, an additional adhesive layer may be further included to bond a rear surface of a second display part DP-2 and the lower plate MP in a bent state of a bending part DP-3.

A size of and/or a shape of each of the adhesive layers AD1 to AD5 may be the same; however, example embodiments are not limited thereto. Alternatively or additionally, a size of and/or a shape of the lower plate MP, the support plate SP, the lower film MP, the optical layer RPL, and the window WL may be the same; however, example embodiments are not limited thereto.

FIG. 3B is a plan view of a display panel in a first mode of the electronic device according to some example embodiments of inventive concepts. FIG. 3C is a plan view of the display panel in the second mode of the electronic device according to some example embodiments of inventive concepts.

FIG. 3B illustrates a display panel DP in an unfolded state for convenience of explanation. However, the display panel DP of FIG. 3B illustrates active areas driven in a state in which a folding area FA of the above-described electronic device ED or ED-a is being folded or is folded.

In addition, FIG. 3C illustrates active areas driven in a state in which the folding area FA of the above-described electronic device ED or ED-a is being unfolded or is unfolded. At this time, the bending part DP-3 may be bent in the first direction DR1 so that a rear surface of a first display part DP-1 and a rear surface of a second display part DP-2 face each other.

Referring to FIGS. 3B and 3C, the display panel DP according to inventive concepts may include the first display part DP-1, the second display part DP-2, and the bending part DP-3. The first display part DP-1 may include a first active area DP-AA1 in which an image provided from pixels is displayed and a first non-active area DP-NAA1 surrounding the first active area DP-AA1. The second display part DP-2 may include a second active area DP-AA2 in which an image provided from pixels is displayed and a second non-active area DP-NAA2 surrounding the second active area DP-AA2.

When the above-described electronic device ED or ED-a is in the first mode, for example, in a state of being folded or being folded about the folding area FA, only the pixels disposed in the second display part DP-2 exposed in the second active area R-AAa may be driven, and the pixels disposed in the first display part DP-1 may not be driven because power is completely turned off. In FIG. 3B, a state in which power to the pixels disposed in the first display part DP-1 is turned off is represented in black.

When the above-described electronic device ED or ED-a is in the second mode, for example, in a state of being unfolded or being unfolded about the folding area FA, the pixels disposed in the second display part DP-2 exposed in the second active area R-AAa may not be driven because power is completely turned off, and only the pixels disposed in the first display part DP-1 may be driven. In FIG. 3C, a state in which power to the pixels disposed in the second display portion DP-2 is turned off is represented in black. Accordingly, an electronic device ED or ED-a with reduced unintended power consumption may be provided depending on a folding operation.

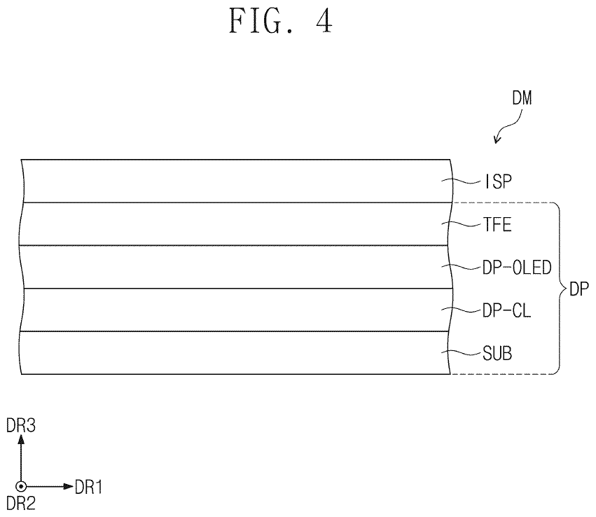

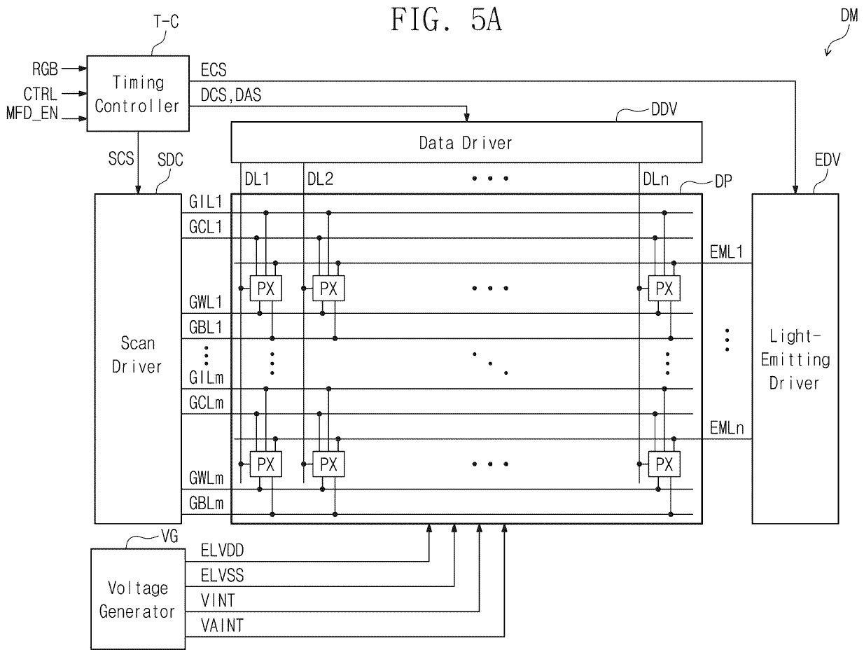

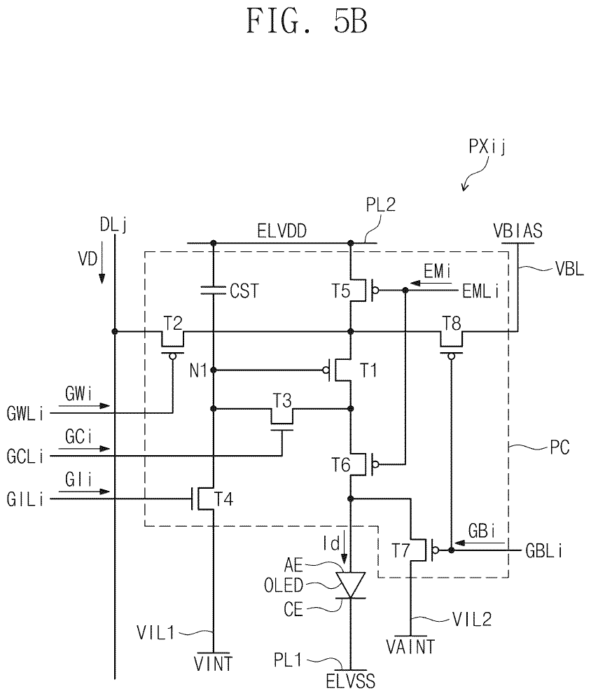

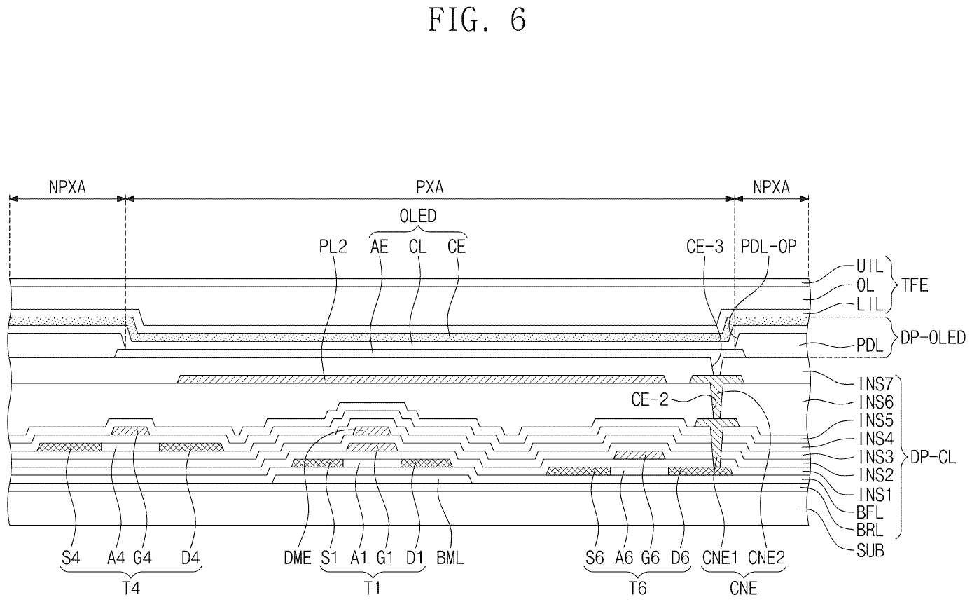

FIG. 4 is a cross-sectional view of a portion of a display module according to some example embodiments of inventive concepts. FIG. 5A is a plan view of the display panel according to some example embodiments of inventive concepts. FIG. 5B is an equivalent circuit diagram of the pixel according to some example embodiments of inventive concepts. FIG. 6 is a cross-sectional view of the display panel according to some example embodiments of inventive concepts.

Referring to FIG. 4, the display module DM may include a display panel DP and an input sensing layer ISP disposed on the display panel DP. The display panel DP may be in a configuration that actually generates an image. The display panel DP may be or may include, or may be included in, a light emission-type display panel. For example, the display panel DP may be or include one or more of an organic light-emitting display panel, an inorganic light-emitting display panel, a micro-LED display panel, a micro-OLED display panel, or a nano-LED display panel.

The display panel DP may include a base layer SUB, a circuit layer DP-CL, a display element layer DP-OLED, and an encapsulation layer TFE, which are sequentially laminated. Unlike what is illustrated, a functional layer may be further disposed between any two adjacent layers of the base layer SUB, the circuit layer DP-CL, the display element layer DP-OLED, and the encapsulation layer TFE.

The base layer SUB may provide a base surface on which the circuit layer DP-CL is disposed. The base layer SUB may be a flexible substrate capable of at least one of bending, folding, or rolling. The base layer SUB may be or may include one or more of a glass substrate, a metal substrate, or a polymer substrate. However, example embodiments are not limited thereto, and the base layer SUB may include one or more of an inorganic layer, an organic layer, or a composite material layer.

The base layer SUB may include a single layer or multiple layers. For example, the base layer SUB may include a first synthetic resin layer, a multilayer or single inorganic layer, and a second synthetic resin layer disposed on the multilayer or single inorganic layer. Each of the first synthetic resin layer and the second synthetic resin layer may include a polyimide-based resin. Alternatively or additionally, each of the first synthetic resin layer and the second synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, the “~~-based” resin means containing a “~~” functional group.

The circuit layer DP-CL may be disposed on the base layer SUB. The circuit layer DP-CL may include an insulating layer, a semiconductor pattern, a conductive pattern, and a signal line. The display element layer DP-OLED may be disposed on the circuit layer DP-CL. The display element layer DP-OLED may include a light-emitting element (not shown). For example, the light-emitting element may include one or more of an organic light-emitting material, an inorganic light-emitting material, an organic-inorganic light-emitting material, quantum dots, quantum rods, micro-LEDs, or nano-LEDs.

The encapsulation layer TFE may be disposed on the display element layer DP-OLED. The encapsulation layer TFE may protect the display element layer DP-ED from foreign substances such as moisture, oxygen, and dust particles. The encapsulation layer TFE may include at least one inorganic layer. For example, the encapsulating layer TFE may include an inorganic layer, an organic layer, and an inorganic layer, which are sequentially laminated.

The input sensing layer ISP may be disposed on the display panel DP. The input sensing layer ISP may be directly disposed on the encapsulation layer TFE. Alternatively, an adhesive member may be disposed between the input sensing layer ISP and the display panel DP.

As used herein, when one component is “directly disposed” on another component, it means that no third component is disposed between the two components. For example, the expression that one component is “directly disposed” on another component means that the two components are “in contact” or “in direct contact” with each other.

The input sensing layer ISP may detect an external input, convert the input into a predetermined input signal, and provide the input signal to the display panel DP. For example, the input sensing layer ISP may be a touch sensing layer that detects a touch. The input sensing layer ISP may recognize a direct touch of a user, an indirect touch of a user, a direct touch of an object, or an indirect touch of an object.

The input sensing layer ISP may detect at least one of a position of a touch and an intensity (pressure) of the touch applied from the outside. The input sensing layer ISP may have various structures or be made of various materials, and is not limited to any one embodiment. For example, the input sensing layer ISP may detect an external input using a capacitive method. The display panel DP may receive an input signal from the input sensing layer ISP and may generate an image corresponding to the input signal.

A thickness of each of the substrate SB, the circuit layer DP-CL, the display element layer DP-OLED, the encapsulating layer TFE, and the input sensing layer ISP may be the same; however, example embodiments are not limited thereto. For example, a thickness of at least one of the substrate SB, the circuit layer DP-CL, the display element layer DP-OLED, the encapsulating layer TFE, and the input sensing layer ISP may be different than a thickness of at least another of the substrate SB, the circuit layer DP-CL, the display element layer DP-OLED, the encapsulating layer TFE, and the input sensing layer ISP.

Referring to FIG. 5A, the electronic device ED or ED-a may include a display panel DP, a timing controller T-C, a scan driver SDV, a data driver DDV, a light emission driver EDV, and the above-described voltage generator VG.

The display panel DP may include a plurality of scan lines GIL1 to GILm, GCL1 to GCLm, GWL1 to GWLm, and GBL1 to GBLm, a plurality of light emission lines EML1 to EMLm, a plurality of data lines DL1 to DLn, and a plurality of pixels PX. Here, m and n are natural numbers.

According to some example embodiments, the pixels PX may be electrically connected to the scan lines GIL1 to GILm, GCL1 to GCLm, GWL1 to GWLm, and GBL1 to GBLm, the light emission lines EML1 to EMLm, and the data lines DL1 to DLn, respectively. Each of the pixels PX may be electrically connected to four corresponding scan lines, one corresponding data line, and one corresponding light emission line. The pixels PX may be disposed in the first display part DP-1 and the second display part DP-2 described in FIG. 3A. The scan lines GIL1 to GILm, GCL1 to GCLm, GWL1 to GWLm, and GBL1 to GBLm may include a plurality of initialization scan lines GIL1 to GILm, a plurality of compensation scan lines GCL1 to GCLm, a plurality of writing scan lines GWL1 to GWLm, and a plurality of bias scan lines GBL1 to GBLm.

Each of the pixels PX may be connected to one (e.g., only one) corresponding initialization scan line of the initialization scan lines GIL1 to GILm, one (e.g., only one) corresponding compensation scan line of the compensation scan lines GCL1 to GCLm, one (e.g., only one) corresponding writing scan line of the writing scan lines GWL1 to GWLm, and one (e.g., only one) corresponding bias scan line of the bias scan lines GBL1 to GBLm.

The scan lines GIL1 to GILm, GCL1 to GCLm, GWL1 to GWLm, and GBL1 to GBLm may be connected to the scan driver SDV, may extend in the first direction DR1, and may be arranged in the second direction DR2. The light emission lines EML1 to EMLm may be connected to the light emission driver EDV, may extend in the first direction DR1, and may be arranged in the second direction DR2. The data lines DL1 to DLn may be connected to the data driver DDV, may extend in the second direction DR2, and may be arranged in the first direction DR1.

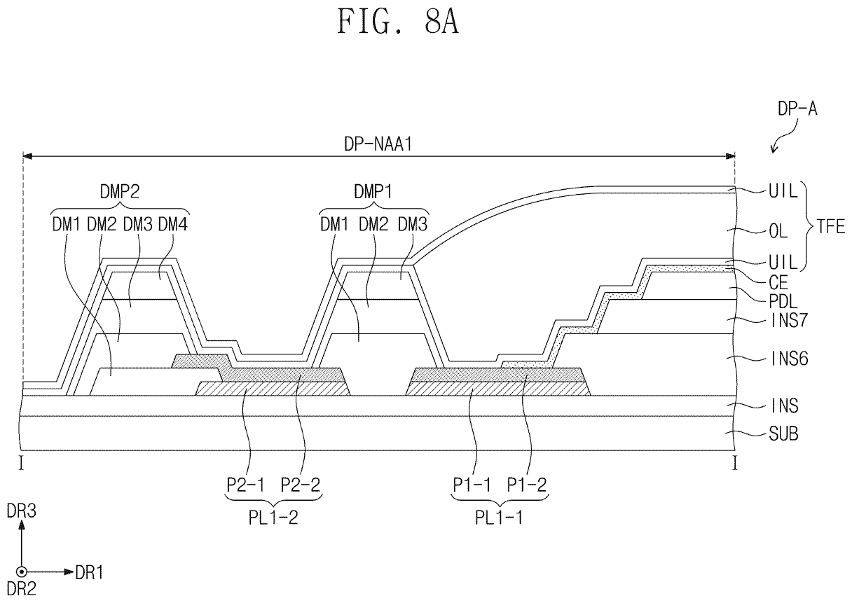

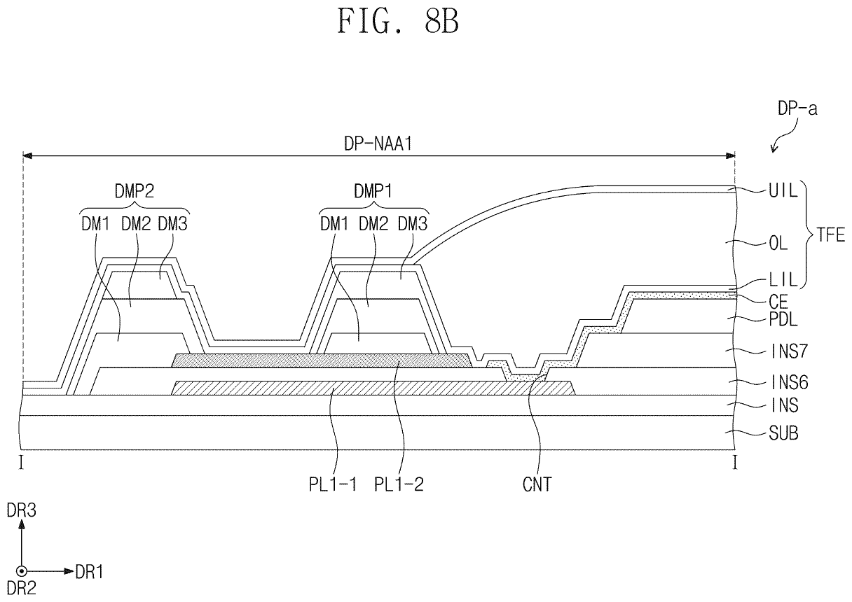

The scan driver SDV, the light emission driver EDV, and the data driver DDV may be substantially disposed in the display panel DP, and these components will be illustrated in FIG. 8.

The timing controller T-C may receive an image signal RGB and a control signal CTRL. The timing controller T-C may generate an image data signal DAS by converting a data format of the image signal RGB to match an interface specification with the data driver DDV. The timing controller T-C may output a scan control signal SCS, a data control signal DCS, and a light emission control signal ECS in response to the control signal CTRL.

The voltage generator VG may generate voltages required for an operation of the display panel DP. The voltage generator VG may generate a first driving voltage ELVSS, a second driving voltage ELVDD, a first initialization voltage VINT, and a second initialization voltage VAINT. The first driving voltage ELVSS, the second driving voltage ELVDD, the first initialization voltage VINT, and the second initialization voltage VAINT may be applied to the pixels PX.

The scan driver SDV may receive a scan control signal SCS from the timing controller T-C. The scan driver SDV may output scan signals to the scan lines GIL1 to GILm, GCL1 to GCLm, GWL1 to GWLm, and GBL1 to GBLm in response to the scan control signal SCS. The scan signals may be applied to the pixels PX through the scan lines GIL1 to GILm, GCL1 to GCLm, GWL1 to GWLm, and GBL1 to GBLm.

The data driver DDV may receive a data control signal DCS and an image data signal DAS from the timing controller T-C. The data driver DDV may convert the image data signal DAS into data signals and output the data signals. The data signals may be defined as analog voltages corresponding to grayscale levels of the image data signal DAS. The data signals may be applied to the pixels PX through the data lines DL1 to DLn.

The light emission driver EDV may receive a light emission control signal ECS from the timing controller T-C. The light emission driver EDV may output light emission signals to the light emission lines EML1 to EMLm in response to the light emission control signal ECS. The light emission signals may be applied to the pixels PX through the light emission lines EML1 to EMLm.

The pixels PX may receive the data voltages in response to the scan signals. The pixels PX may emit light having brightness corresponding the data voltages in response to the emission signals to display an image.

FIG. 5B is a diagram illustrating an equivalent circuit of one of the pixels illustrated in FIG. 5A. A pixel circuit PC structure of the pixel, which will be described below, may be commonly applied to the pixels disposed in the first display part DP-1 and the second display part DP-2 described in FIG. 3A. For example, FIG. 5B illustrates a pixel PXij connected to a j-th data line DLj, i-th scan lines GWLi, GCLi, GILi, and GBLi, and an i-th light-emission line EMLi. Here, i and j are natural numbers.

Referring to FIG. 5B, the pixel PXij may include a pixel circuit PC and a light-emitting element OLED connected to the pixel circuit PC. The pixel circuit PC may drive the light-emitting element OLED.

The pixel circuit PC may include a plurality of transistors T1 to T8 and a capacitor CST. The pixel circuit PC may be an 8T1C pixel circuit; however, example embodiments are not limited thereto. The transistors T1 to T8 and the capacitor CST may control an amount of current flowing through the light-emitting element OLED. The light-emitting element OLED may generate light having a predetermined luminance according to the supplied amount of current.

The i-th writing scan line GWLi may receive an i-th writing scan signal GWi, and the i-th compensation scan line GCLi may receive an i-th compensation scan signal GCi. The i-th initialization scan line GILi may receive an i-th initialization scan signal GIi, and the i-th bias scan line GBLi may receive an i-th bias scan signal GBi. The i-th light emission line EMLi may receive an i-th light emission signal EMi.

The pixel PXij may be connected to a j-th data line DLj, the i-th writing scan line GWLi, the i-th compensation scan line GCLi, the i-th initialization scan line GILi, the i-th bias scan line GBLi, the i-th light emission line EMLi, a first initialization line VIL1, a second initialization line VIL2, a bias line VBL, and first and second power lines PL1 and PL2.

The first initialization line VIL1 may receive a first initialization voltage VINT, and the second initialization line VIL2 may receive a second initialization voltage VAINT. The bias line VBL may receive a bias voltage VBIAS. The first power line PL1 may receive a first driving voltage ELVSS, and the second power line PL2 may receive a second driving voltage ELVDD. According to some example embodiments, the first power line PL1 may receive the second driving voltage ELVDD, and the second power line PL2 may receive the first driving voltage ELVSS, and the names of the first and second power lines may vary depending on inventive concepts.

Each of the transistors T1 to T8 may include a source electrode, a drain electrode, and a gate electrode. Hereinafter, for convenience of description in FIG. 5B, one of the source and drain electrodes is defined as a first electrode, and the other is defined as a second electrode. In addition, the gate electrode is defined as a control electrode.

The transistors T1 to T8 may include first to eighth transistors T1 to T8. The first, second, and fifth to eighth transistors T1, T2, and T5 to T8 may be PMOS transistors; however, example embodiments are not limited thereto. The third and fourth transistors T3 and T4 may be NMOS transistors; however, example embodiments are not limited thereto. Electrical properties (e.g., threshold voltages, drive currents, etc.) and/or physical properties (e.g., gate thicknesses, gate widths, gate lengths, etc.) may be the same for each of transistors T1, T2, and T5 to T8, and for each of the transistors T3 and T4; however, example embodiments are not limited thereto, and at least one transistor may have different electrical and/or physical properties than at least one other transistor.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light emission control transistors. The eighth transistor T8 may be defined as a bias transistor.

The light-emitting element OLED may be or may include an organic light-emitting diode. The light-emitting element OLED may include a first electrode AE and a second electrode CE. The first electrode AE may receive a second driving voltage ELVDD through a sixth transistor T6, a first transistor T1, and a fifth transistor T5. The second driving voltage ELVDD may be applied to the pixel circuit PC through the second power line PL2.

The second electrode CE may receive a first driving voltage ELVSS having a level lower than that of the second driving voltage ELVDD. The first driving voltage ELVSS may be applied to the pixel circuit PC through the first power line PL1.

The first transistor T1 may be disposed between the fifth transistor T5 and the sixth transistor T6 and may be connected to the fifth transistor T5 and the sixth transistor T6. The first transistor T1 may be connected to the second power line PL2 through the fifth transistor T5, and may be connected to the first electrode AE through the sixth transistor T6.

The first transistor T1 may include a first electrode connected to the second power line PL2 through the fifth transistor T5, a second electrode connected to the first electrode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control an amount of current flowing through the light-emitting element OLED according to a voltage of the first node N1 applied to the control electrode of the first transistor T1.

The second transistor T2 may be disposed between the first transistor T1 and the j-th data line DLj, and may be connected to the first transistor T1 and the j-th data line DLj. The second transistor T2 may include a first electrode connected to the j-th data line DLj, a second electrode connected to the first electrode of the first transistor T1, and a control electrode connected to the i-th writing scan line GWLi.

The second transistor T2 may be turned on by an i-th writing scan signal GWi applied through the i-th writing scan line GWLi to electrically connect the j-th data line DLj and the first electrode of the first transistor T1. The second transistor T2 may perform a switching operation of supplying a data voltage VD (corresponding to the above-described data signal) received through the j-th data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a control electrode connected to the i-th compensation scan line GCLi.

The third transistor T3 may be turned on by an i-th compensation scan signal GCi applied through the i-th compensation scan line GCLi to electrically connect the second electrode and the control electrode of the first transistor T1. When the third transistor T3 is turned on, the first transistor T1 and the third transistor T3 may be connected in a diode configuration.

The fourth transistor T4 may be connected to the first node N1. The fourth transistor T4 may include a first electrode connected to the first node N1, a second electrode connected to the first initialization line VIL1, and a control electrode connected to the i-th initialization scan line GILi. The fourth transistor T4 may be turned on by an i-th initialization scan signal GIi applied through the i-th initialization scan line GILi to provide a first initialization voltage VINT received through the first initialization line VIL1 to the first node N1.

The fifth transistor T5 may include a first electrode connected to the second power line PL2, a second electrode connected to the first electrode of the first transistor T1, and a control electrode connected to the i-th light emission line EMLi.

The sixth transistor T6 may include a first electrode connected to the second electrode of the first transistor T1, a second electrode connected to the first electrode AE, and a control electrode connected to the i-th light emission line EMLi.

The fifth transistor T5 and the sixth transistor T6 may be turned on by an i-th light emission signal EMi applied through the i-th light emission line EMLi. The second driving voltage ELVDD may be supplied to the light-emitting element OLED by the fifth transistor T5 and the sixth transistor T6, which are turned on, a driving current may flow through the light-emitting element OLED. Accordingly, the light-emitting element OLED may emit light.

The seventh transistor T7 may include a first electrode connected to the first electrode AE, a second electrode connected to the second initialization line VIL2, and a control electrode connected to the i-th bias scan line GBLi. The seventh transistor T7 may be turned on by an i-th bias scan signal GBi applied through the i-th bias scan line GBLi to provide a second initialization voltage VAINT received through the second initialization line VIL2 to the first electrode AE of the light-emitting element OLED.

In some example embodiments, the second initialization voltage VAINT may have a level different from that of the first initialization voltage VINT, but is not limited thereto and may have the same level as the first initialization voltage VINT.

The seventh transistor T7 may improve black expression ability of the pixel PXij. When the seventh transistor T7 is turned on, a parasitic capacitor (not shown) of the light-emitting element OLED may be discharged. Accordingly, when implementing black luminance, the light-emitting element OLED may not emit light due to the leakage current of the first transistor T1, and thus black representation performance may be improved.

The capacitor CST may include a first electrode connected to the second power line PL2 and a second electrode connected to the first node N1. When the fifth transistor T5 and the sixth transistor T6 are turned on, the amount of current flowing through the first transistor T1 may be determined based on a voltage stored in the capacitor CST.

The eighth transistor T8 may include a first electrode connected to the bias line VBL, a second electrode connected to the first electrode of the first transistor T1, and a control electrode connected to the i-th bias scan line GBLi.

The eighth transistor T8 may be turned on by the i-th bias scan signal GBi and may supply a bias voltage VBIAS, received through the bias line VBL, to the first electrode of the first transistor T1. However, the transistors included in the pixel PXij are not limited thereto.

FIG. 6 is a cross-sectional view of a pixel PX disposed in the display panel DP. Referring to FIG. 6, the light-emitting element OLED according to one embodiment may include a first electrode AE, a second electrode CE, and a common layer CL. The common layer CL may include a hole control layer, an electron control layer, and an emission layer.

The second electrode CE may be disposed on the first electrode AE, and the common layer CL may be disposed between the first electrode AE and the second electrode CE. The light-emitting element OLED according to some example embodiments may further include a protective layer disposed on the second electrode CE. The protective layer may include an organic material and may prevent or reduce the likelihood of and/or the impact from damage to components disposed below the protective layer during subsequent processes. According to some example embodiments, the protective layer may be omitted.

The second driving voltage ELVDD may be applied to the first electrode AE, and the first driving voltage ELVSS may be applied to the second electrode CE. Holes and electrons injected into the common layer CL may recombine to form excitons, and when the excitons transition to a ground state, the light-emitting element OLED may emit light. As the light-emitting element OLED emits light, an image may be displayed.

The first transistor T1, the fourth transistor T4, the sixth transistor T6, and the light-emitting element OLED may be disposed on the base layer SUB. Each of the first and second active areas DP-AA1 and DP-AA2 described in FIG. 3B may include an emission area PXA corresponding to the pixel PXij (see FIG. 5B) and a non-emission area NPXA adjacent to the emission area PXA.

The base layer SUB may include glass and/or a flexible plastic material such as polyimide (PI). A circuit element layer DP-CL, a display element layer DP-OLED, and a thin film encapsulation layer TFE may be disposed on the base layer SUB. The circuit element layer DP-CL may be disposed on the base layer SUB. The circuit element layer DP-CL may include insulating layers and conductive patterns. The display element layer DP-OLED may include the light-emitting element OLED and a pixel defining layer PDL.

A barrier layer BRL may be disposed on the base layer SUB. The barrier layer BRL may enhance adhesion between a semiconductor pattern included in the transistors and the base layer SUB. The barrier layer BRL may include an inorganic material.

A metal layer BML may be disposed on the barrier layer BRL. The metal layer BML may overlap the first transistor T1. According to some example embodiments, the metal layer BML may be supplied with a constant voltage. When a constant voltage is applied to the metal layer BML, a threshold voltage Vth of the first transistor T1 disposed on the metal layer BML may be maintained without change.

The metal layer BML may block light incident from below the metal layer BML into the first transistor T1. The metal layer BML may include a reflective metal. According to some example embodiments, the metal layer BML may be omitted.

A buffer layer BFL may be disposed on the barrier layer BRL and may cover the metal layer BML. The buffer layer BFL may include an inorganic material.

A semiconductor layer S1, A1, D1 of the first transistor T1 and a semiconductor layer S6, A6, D6 of the sixth transistor T6 may be disposed on the buffer layer BFL. The semiconductor layers S1, A1, D1, S6, A6, and D6 may include polysilicon. However, the semiconductor layers S1, A1, D1, S6, A6, and D6 may alternatively or additionally include amorphous silicon and are not limited thereto.

The semiconductor layers S1, A1, D1, S6, A6, and D6 may be doped with an N-type dopant such as but not limited to arsenic and/or phosphorus. Alternatively or additionally, the semiconductor layers S1, A1, D1, S6, A6, and D6 may be doped with a P-type dopant such as but not limited to boron. The semiconductor layers S1, A1, D1, S6, A6, and D6 may include a high-doping region and a low-doping region. The high-doping region may have higher conductivity than that in the low-doping region and may substantially serve as source and drain electrodes of the first and sixth transistors T1 and T6. The low-doping region may substantially correspond to an active (or channel) region of the first and sixth transistors T1 and T6.

A first source region S1, a first channel region A1, and a first drain region D1 of the first transistor T1 may be formed from the semiconductor layer S1, A1, D1. A sixth source region S6, a sixth channel region A6, and a sixth drain region D6 of the sixth transistor T6 may be formed from the semiconductor layer S6, A6, D6. The first channel region A1 may be disposed between the first source region S1 and the first drain region D1. The sixth channel region A6 may be disposed between the sixth source region S6 and the sixth drain region D6.

A first insulating layer INS1 may be disposed on the buffer layer BFL to cover the semiconductor layers S1, A1, D1, S6, A6, and D6. A first gate electrode G1 (or control electrode) of the first transistor T1 and a sixth gate electrode G6 (or control electrode) of the sixth transistor T6 may be disposed on the first insulating layer INS1. In a top view, the first gate electrode G1 may overlap the first channel region A1, and the sixth gate electrode G6 may overlap the sixth channel region A6.

According to some example embodiments, the structure of the source region, channel region, drain region, and gate electrode of each of the second, fifth, and seventh transistors T2, T5, and T7 may be substantially the same as that of the first and sixth transistors T1 and T6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed above the first gate electrode G1 and, in a top view, may overlap the first gate electrode G1. The dummy electrode DME may provide the above-described capacitor together with the first gate electrode G1.

A third insulating layer INS3 may be disposed on the second insulating layer INS2 to cover the dummy electrode DME. Semiconductor layers S4, A4, and D4 of the fourth transistor T4 may be disposed on the third insulating layer INS3. Each of the semiconductor layers S4, A4, and D4 may include an oxide semiconductor composed of a metal oxide. Oxide semiconductors may include crystalline and/or amorphous oxide semiconductors.

The semiconductor layers S4, A4, and D4 may include a plurality of regions distinguished according to whether the metal oxide is reduced. A region in which the metal oxide is reduced (hereinafter, reduced region) may have higher conductivity than a region in which the metal oxide is not reduced (hereinafter, non-reduced region). The reduced region may substantially serve as a source electrode or a drain electrode of the fourth transistor T4. The non-reduced region may substantially correspond to an active region (or channel) of the fourth transistor T4.

A fourth source region S4, a fourth channel region A4, and a fourth drain region D4 of the fourth transistor T4 may be provided from the semiconductor layers S4, A4, and D4. The fourth channel region A4 may be disposed between the fourth source region S4 and the fourth drain region D4.

A fourth insulating layer INS4 may be disposed on the third insulating layer INS3 to cover the semiconductor layer S4, A4, D4. A fourth gate electrode G4 of the fourth transistor T4 may be disposed on the fourth insulating layer INS4. In a top view, the fourth gate electrode G4 may overlap the fourth channel region A4.

A fifth insulating layer INS5 may be disposed on the fourth insulating layer INS4 to cover the fourth gate electrode G4. Although not shown, the source region, channel region, drain region, and gate electrode structure of the third transistor T3 may be substantially the same as that of the fourth transistor T4.

The barrier layer BRL, the buffer layer BFL, and the first to fifth insulating layers INS1 to INS5 may include an inorganic material. For example, the barrier layer BRL, the buffer layer BFL, and the first to fifth insulating layers INS1 to INS5 may include either or both of silicon oxide or silicon nitride, or one insulating layer may include multiple inorganic layers, and are not limited to any particular embodiment. The multiple inorganic layers may have a laminated structure in which layers including silicon nitride and silicon oxide are alternately laminated.

A connection electrode CNE may be disposed between the sixth transistor T6 and the light-emitting element OLED. The connection electrode CNE may electrically connect the sixth transistor T6 to the light-emitting element OLED. The connection electrode CNE may include a first connection electrode CNE1 and a second connection electrode CNE2 disposed on the first connection electrode CNE1.

The first connection electrode CNE1 may be disposed on the fifth insulating layer INS5 and may be connected to the sixth drain region D6 through a first contact hole CH1 defined in the first to fifth insulating layers INS1 to INS5. A sixth insulating layer INS6 may be disposed on the fifth insulating layer INS5 to cover the first connection electrode CNE1.

The second connection electrode CNE2 may be disposed on the sixth insulating layer INS6. The second connection electrode CNE2 may be connected to the first connection electrode CNE1 through a second contact hole CH2 defined in the sixth insulating layer INS6.

According to some example embodiments, the second power line PL2 may be disposed on the sixth insulating layer INS6 and may be covered by a seventh insulating layer INS7. According to some example embodiments, a portion of the second power line PL2 may be disposed in the emission area PXA. The second power line PL2 and the second connection electrode CNE2 may be patterned by the same process and may include the same material.

The seventh insulating layer INS7 may be disposed on the sixth insulating layer INS6 to cover the second connection electrode CNE2 and the second power line PL2. The sixth and seventh insulating layers INS6 and INS7 may include an organic material.

A pixel defining layer PDL may be disposed on the seventh insulating layer INS7. An opening PDL-OP may be defined in the pixel defining layer PDL to expose at least a portion of the first electrode AE. In some example embodiments, the pixel defining layer PDL may include an organic material. In addition, the pixel defining layer PDL may have a particular color, such as a predetermined color, and is not limited to any particular embodiment.

A common layer CL and a second electrode CE included in the light-emitting element OLED may be disposed on the pixel defining layer PDL.

A thin encapsulation layer TFE may be disposed on the light-emitting element OLED to cover the light-emitting element OLED. The thin film encapsulation layer TFE may include a first inorganic layer LIL, an organic layer OL, and a second inorganic layer IL2, which are sequentially laminated. The first and second inorganic layers LIL and IL2 may include an inorganic material and may protect or help protect the pixels from moisture and oxygen. The organic layer OL may include an organic material and may protect the pixels PX from foreign substances such as dust particles.

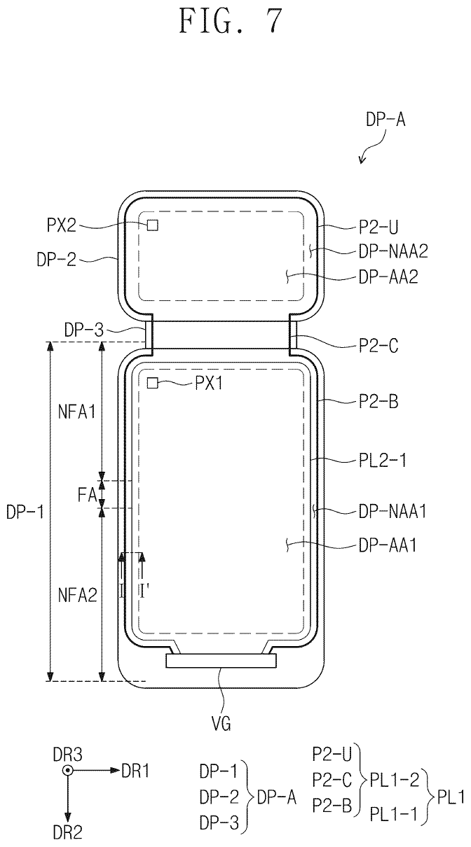

FIG. 7 is a plan view of the display panel according to some example embodiments of inventive concepts. FIG. 8A is a cross-sectional view taken along line I-I′ of FIG. 7 according to some example embodiments of inventive concepts. FIG. 8B is a cross-sectional view taken along line I-I′ of FIG. 7 according to some example embodiments of inventive concepts.

FIG. 7 illustrates the first power line PL1 disposed on the display panel DP-A, as shown in FIGS. 5A and 5B. According to some example embodiments, a display panel DP-A may include a first display part DP-1, a second display part DP-2, and a bending part DP-3.

The first display part DP-1 may include a folding area FA and first and second non-folding areas NFA1 and NFA2 spaced apart from each other along a second direction DR2 with the folding area FA therebetween. The folding area FA may be in-folded about a folding axis extending in a first direction DR1.

The first display part DP-1 may include a first active area DP-AA1 and a first peripheral area DP-NAA1 surrounding the first active area DP-AA1. First pixels PX1 may be disposed in the first active area DP-AA1.

A voltage generator VG may be disposed in the first peripheral area DP-NAA1. However, this is merely illustrative, and the voltage generator VG may be disposed outside the display panel DP-A, and a data driver DDV (see FIG. 5A) may be disposed in the first peripheral area DP-NAA1. These configurations are not limited to any particular embodiment.

The second display part DP-2 may include a second active area DP-AA2 and a second peripheral area DP-NAA2 surrounding the second active area DP-AA2. Second pixels PX2 may be disposed in the second active area DP-AA2. According to some example embodiments, the first pixels PX1 and the second pixels PX2 may be driven independently according to an operation state of the display panel DP-A.

A first power line PL1 described in FIGS. 5A and 5B, may be disposed on the display panel DP-A. The first power line PL1 may supply a first driving voltage ELVSS (see FIG. 5A) to the first pixels PX1 and the second pixels PX2.

The first power line PL1 may include a (1-1)-th power line PL1-1 connected to the first pixels PX1 and the voltage generator VG, and a (1-2)-th power line PL1-2 connected to the second pixels PX2 and the voltage generator VG.

The (1-1)-th power line PL1-1 may be disposed in the first peripheral area DP-NAA1 and may surround the first active area DP-AA1. The (1-1)-th power line PL1-1 may be disposed relatively closer to the first active area DP-AA1 than the (1-2)-th power line PL1-2. The (1-1)-th power line PL1-1 may be connected to a second electrode CE (see FIG. 6) commonly disposed in the first pixels PX1 in the first peripheral area DP-NAA1.

The (1-2) power line PL1-2 may include a first line P2-B disposed in the first peripheral area DP-NAA1, a second line P2-C disposed in the bending part DP-3, and a third line P2-U disposed in the second peripheral area DP-NAA2.

One portion of the first line P2-B may be disposed on one side of the first peripheral area DP-NAA1, and another portion of the first line P2-B may be disposed on the other side thereof. The third line P2-U may surround at least a portion of the second peripheral area DP-NAA2. The second line P2-C may connect the first line P2-B and the third line P2-U, which are spaced apart with the bending part DP-3 therebetween.

Accordingly, the second line P2-C may be stored in the housing HAU (see FIG. 3A) in a bent shape corresponding to the bent shape of the bending part DP-3. The third line P2-U may be connected to a second electrode CE (see FIG. 6) commonly disposed in the second pixels PX2 in the second peripheral area DP-NAA2.

Hereinafter, an “interlayer insulating layer” INS may refer to a single layer depicted as covering from a barrier layer BRL to a fifth insulating layer INS5 as described in FIG. 6.

Referring to FIG. 8A, the interlayer insulating layer INS may be disposed on a base layer SUB. The (1-1)-th power line PL1-1 and the (1-2)-th power line PL1-2 may be disposed on the interlayer insulating layer INS. The (1-1)-th power line PL1-1 and the (1-2)-th power line PL1-2 may be spaced apart from each other, and the (1-1)-th power line PL1-1 may be disposed relatively closer to the first active area DP-AA1 than the (1-2)-th power line PL1-2.

The display panel DP-A according to some example embodiments may include dam parts DMP1 and DMP2. The dam parts DMP1 and DMP2 may surround the first peripheral area DP-NAA1 and the second peripheral area DP-NAA2. The first dam part DMP1 may be disposed relatively closer to the first active area DP-AA1 than the second dam part DMP2. Accordingly, the second dam part DMP2 may surround at least a portion of the first dam part DMP1.

Each of the dam parts DMP1 and DMP2 may include multiple-laminated organic layers. The first dam part DMP1 may include first to third layers DM1, DM2, and DM3, and the second dam part DMP2 may include first to fourth layers DM1, DM2, DM3, and DM4. The layers included in the first and second dam parts DMP1 and DMP2 may include the same material as any one of a sixth insulating layer INS6, a seventh insulating layer INS7, a pixel defining layer PDL, and a spacer. The spacer may be or may include an organic pattern disposed on the pixel defining layer PDL and may support a mask during a deposition process.

At least one of the first and second dam parts DMP1 and DMP2 may define a boundary of the organic layer OL in the first and second peripheral areas DP-NAA1 and DP-NAA2. The dam parts may prevent or reduce the likelihood that the organic layer OL from overflowing into the first and second peripheral areas DP-NAA1 and DP-NAA2 during a forming process.

According to some example embodiments, the (1-1)-th power line PL1-1 and the (1-2)-th power line PL1-2 may be spaced apart from each other with the first dam part DMP1 therebetween. A portion of each of the (1-1)-th power line PL1-1 and the (1-2)-th power line PL1-2 may be covered by the first dam part DMP1.

According to some example embodiments, each of the (1-1)-th power line PL1-1 and the (1-2)-th power line PL1-2 may be implemented as a multilayer structure. The (1-1)-th power line PL1-1 may include a first conductive layer P1-1 disposed on the interlayer insulating layer INS and a second conductive layer P1-2 directly disposed on the first conductive layer P1-1. The (1-2)-th power line PL1-2 may include a first conductive layer P2-1 disposed on the interlayer insulating layer INS and a second conductive layer P2-2 directly disposed on the first conductive layer P2-1.

The first conductive layers P1-1 and P2-1 may include the same material as a first connection electrode CNE1 described in FIG. 6, and the second conductive layers P1-2 and P2-2 may include the same material as a second connection electrode CNE2 described in FIG. 6. According to some example embodiments, each of the conductive layers P1-1, P1-2, P2-1, and P2-2 may include sequentially laminated metal layers, and the metal layers may be titanium/aluminum/titanium.

In the first peripheral area DP-NAA1, the (1-1)-th power line PL1-1 may be connected to the second electrode CE commonly disposed in the first pixels PX1. According to some example embodiments, in the second peripheral area DP-NAA2, the (1-2)-th power line PL1-2 may be connected to the second electrode CE commonly disposed in the second pixels PX2.

According to some example embodiments, the (1-1)-th power line PL1-1 may not be disposed in the second peripheral area DP-NAA2, and only the (1-2)-th power line PL1-2 may be disposed therein.

FIG. 8B mainly describes differences from FIG. 8A. Referring to FIG. 8B, the (1-1)-th power line PL1-1 may be disposed on the interlayer insulating layer INS and may be covered by the sixth insulating layer INS6. The (1-2)-th power line PL1-2 may be disposed on the sixth insulating layer INS6 and may be covered by the seventh insulating layer INS7. Accordingly, the (1-1)-th power line PL1-1 and the (1-2)-th power line PL1-2 may overlap in the first peripheral area DP-NAA1.

A portion of the (1-1)-th power line PL1-1 may be connected to the second electrode CE commonly disposed in the first pixels PX1 through a contact hole CNT defined in the sixth insulating layer INS6.

According to some example embodiments, the (1-1)-th power line PL1-1 may not be disposed in the second peripheral area DP-NAA2, and only the (1-2)-th power line PL1-2 may be disposed therein.

According to some example embodiments, in a first mode, a voltage may not be supplied from the voltage generator VG to the (1-1)-th power line PL1-1, and power may be supplied only to the (1-2)-th power line PL1-2. Accordingly, in the first mode, only the second pixels PX2 may be driven, and the first pixels PX1 may be in a completely turned-off state. As described with reference to FIG. 2F, in the first mode, the first pixels PX1 disposed in the first active area F-AAa may be in a completely turned-off state, and the second pixels PX2 disposed in the second active area R-AAa may be driven.

In contrast to inventive concepts, when the first pixels PX1 are driven to display a black state on the screen in the first mode, unintended power may be supplied, and thus, power consumption may increase. The increased power consumption may reduce available battery charge.

In a second mode, a voltage may not be supplied from the voltage generator VG to the (1-2)-th power line PL1-2, and power may be supplied only to the (1-1)-th power line PL1-1. Accordingly, in the second mode, only the first pixels PX1 may be driven, and the second pixels PX2 may be in a completely turned-off state. As described with reference to FIG. 2F, in the second mode, the second pixels PX2 disposed in the second active area R-AAa may be in a completely turned-off state, and the first pixels PX1 disposed in the first active area F-AAa may be driven.

In contrast to inventive concepts, when the second pixels PX2 are driven to display a black state on the screen in the second mode, unintended power may be supplied, and thus, power consumption may increase. The increased power consumption may reduce available battery charge.

According to inventive concepts, unintended power consumption may be reduced by completely turning off power supplied to pixels that do not need to be driven according to an operation mode of the electronic device ED or ED-a. Accordingly, an electronic device ED or ED-a with reduced power consumption and/or a longer battery life may be provided.

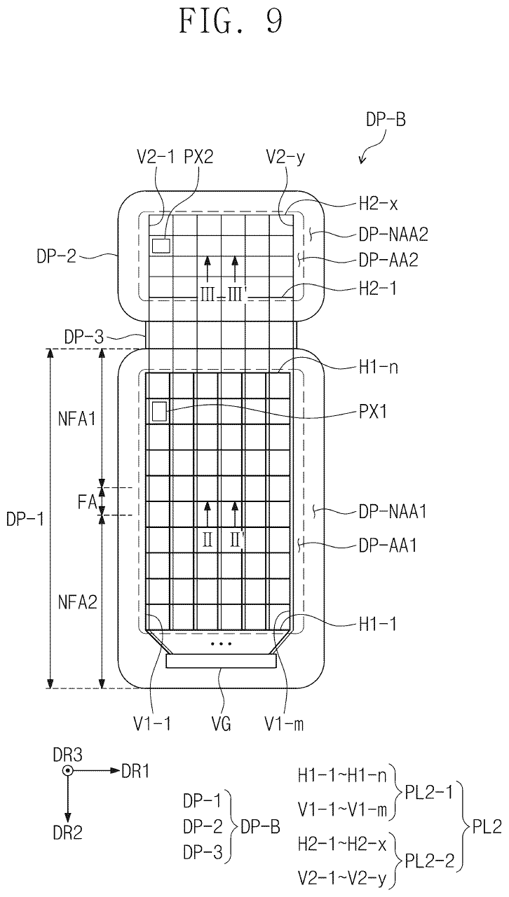

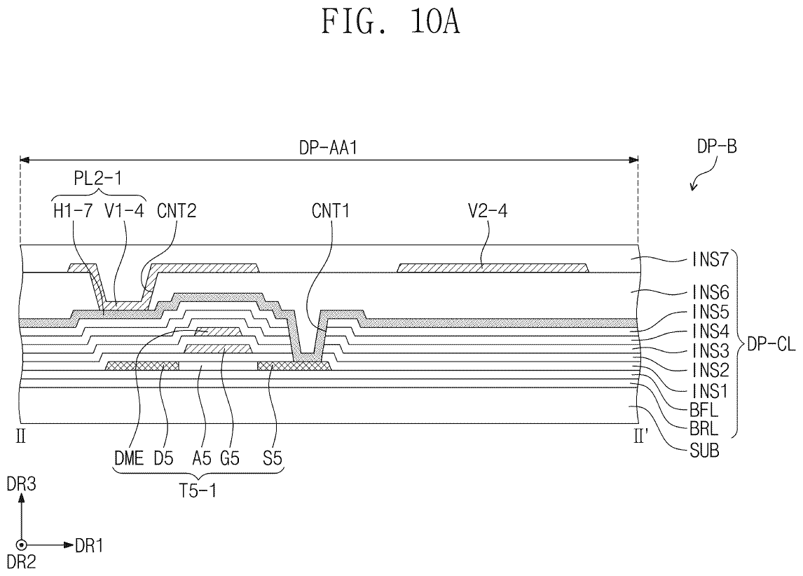

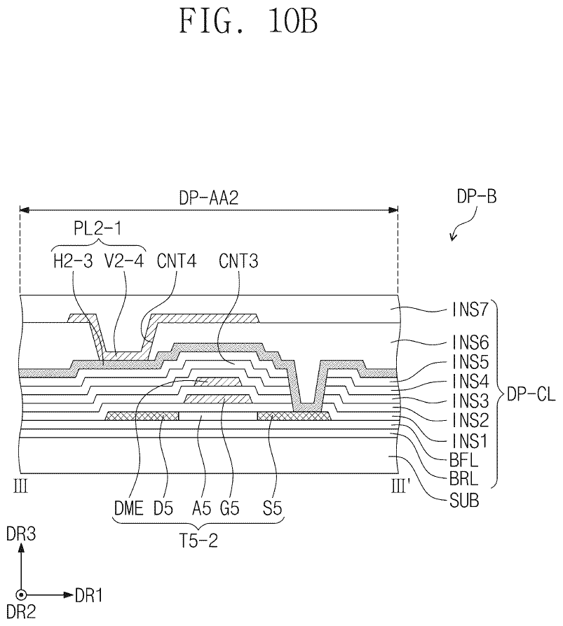

FIG. 9 is a plan view of a display panel according to some example embodiments. FIG. 10B is a cross-sectional view taken along line II-II′ of FIG. 9 according to some example embodiments of inventive concepts. FIG. 10B is a cross-sectional view taken along line III-III′ of FIG. 9 according to some example embodiments of inventive concepts.

FIG. 9 illustrates a second power line PL2 disposed in a display panel DP-b1, as shown in FIGS. 5A and 5B. According to some example embodiments, the display panel DP-b1 may include a first display part DP-1, a second display part DP-2, and a bending part DP-3.

The first display part DP-1 may include a folding area FA and first and second non-folding areas NFA1 and NFA2 spaced apart from each other along a second direction DR2 with the folding area FA therebetween. The folding area FA may be in-folded about a folding axis extending in a first direction DR1.

The first display part DP-1 may include a first active area DP-AA1 and a first peripheral area DP-NAA1 surrounding the first active area DP-AA1. First pixels PX1 may be disposed in the first active area DP-AA1.

A voltage generator VG may be disposed in the first peripheral area DP-NAA1. However, this is merely illustrative, and the voltage generator VG may be disposed outside the display panel DP-A, and a data driver DDV (see FIG. 5A) may be disposed in the first peripheral area DP-NAA1. These configurations are not limited to any particular example embodiment.

The second display part DP-2 may include a second active area DP-AA2 and a second peripheral area DP-NAA2 surrounding the second active area DP-AA2. Second pixels PX2 may be disposed in the second active area DP-AA2. According to some example embodiments, the first pixels PX1 and the second pixels PX2 may be individually driven depending on the operating state of the display panel DP-b1.

The display panel DP-b1 may include a second power line PL2 as described in FIGS. 5A and 5B. The second power line PL2 may supply a second driving voltage ELVDD (see FIG. 5A) to the first pixels PX1 and the second pixels PX2.

The second power line PL2 may include a (2-1)-th power line PL2-1 connected to the first pixels PX1 and the voltage generator VG, and a (2-2)-th power line PL2-2 connected to the second pixels PX2 and the voltage generator VG.

The (2-1)-th power line PL2-1 may include a plurality of (1-1)-th lines H1-1 to H1-n (where ‘n’ is a natural number greater than 0), each extending along a first direction DR1 and arranged along a second direction DR2, and a plurality of (1-2)-th lines V1-1 to V1-m (where ‘m’ is a natural number greater than 0), each extending along the second direction DR2 and arranged along the first direction DR1.

The (1-1)-th lines H1-1 to H1-n and the (1-2)-th lines V1-1 to V1-m may intersect each other within the first active area DP-AA1. The (1-1)-th lines H1-1 to H1-n and the (1-2)-th lines V1-1 to V1-m may overlap with the emission area PXA and the non-emission area NPXA as described in FIG. 6.

The (1-1)-th lines H1-1 to H1-n may be disposed in the first active area DP-AA1. The (1-2)-th lines V1-1 to V1-m may be connected to the voltage generator VG, and may be disposed in the first active area DP-AA1 through the first peripheral area DP-NAA1 from the voltage generator VG.

The (2-2)-th power line PL2-2 may include a plurality of (2-1)-th lines H2-1 to H2-x (where ‘x’ is a natural number greater than 0), each extending along a first direction DR1 and arranged along a second direction DR2, and a plurality of (2-2)-th lines V2-1 to V2-y (where ‘y’ is a natural number greater than 0), each extending along the second direction DR2 and arranged along the first direction DR1.

The (2-1)-th lines H2-1 to H2-x and the (2-2)-th lines V2-1 to V2-y may intersect each other within the second active area DP-AA2. The (2-1)-th lines H2-1 to H2-x and the (2-2)-th lines V2-1 to V2-y may overlap with the emission area PXA and the non-emission area NPXA as described in FIG. 6.

The (2-1)-th lines H2-1 to H2-x may be disposed only in the second active area DP-AA2. The (2-2)-th lines V2-1 to V2-y may be connected to the voltage generator VG, and may be disposed in the second active area DP-AA2 through the first peripheral area DP-NAA1, the first active area DP-AA1, a bending part DP-3, and the second peripheral area DP-NAA2 from the voltage generator VG.

Each of the (2-2)-th lines V2-1 to V2-y disposed in the first active area DP-AA1 may be disposed adjacent to the corresponding (1-2)-th line V1-1 to V1-m, and may intersect the (1-1)-th lines H1-1 to H1-n.

FIG. 10A illustrates one of the (1-1)-th lines H1-1 to H1-n disposed in the first active area DP-AA1, namely the (1-1)-th line H1-7, one of the (1-2)-th lines V1-1 to V1-m, namely the (1-2)-th line V1-4, and one of the (2-2)-th lines V2-1 to V2-y, namely the (2-2)-th line V2-4.

The (1-1)-th line H1-7 may be disposed on a fifth insulating layer INS5 and may extend along the first direction DR1. The (1-1)-th line H1-7 may be covered by a sixth insulating layer INS6. The (1-1)-th line H1-7 may include the same material as a first connection electrode CNE1 described in FIG. 6.

The (1-1)-th line H1-7 may be connected to a fifth transistor T5-1 included in the first pixels PX1 through a first contact hole CNT1 penetrating the first to fifth insulating layers INS1 to INS5. The fifth transistor T5-1 may correspond to the fifth transistor T5 described in FIG. 5b.

According to some example embodiments, the (1-1)-th line H1-7 may intersect the (1-2)-th line V1-4 and the (2-2)-th line V2-4 in the first active area DP-AA1, and may be disposed on different layers.

The (1-2)-th line V1-4 may be disposed on the sixth insulating layer INS6 and may be covered by a seventh insulating layer INS7. The (1-2)-th line V1-4 may be spaced apart from the (2-2)-th line V2-4 along the second direction DR2. The (1-2)-th line V1-4 and the (2-2)-th line V2-4 may include the same material as a second connection electrode CNE2 described in FIG. 6. The (1-2)-th line V1-4 may be connected to the (1-1)-th line H1-7 through a second contact hole CNT2 penetrating the sixth insulating layer INS6. Since the (2-1)-th power line PL2-1 includes lines disposed on different layers and connected through contact holes, this may reduce resistance in the first active area DP-AA1.

FIG. 10B illustrates one of the (2-1)-th lines H2-1 to H2-x, namely the (2-1)-th line H2-3, and one of the (2-2)-th lines V2-1 to V2-y, namely the (2-2)-th line V2-4, disposed in the second active area DP-AA2. The (2-1)-th power line PL2-1 may not be disposed in the second active area DP-AA2.

The (2-1)-th line H2-3 may be disposed on a fifth insulating layer INS5 and may extend along a first direction DR1. The (2-1)-th line H2-3 may be covered by a sixth insulating layer INS6. The (2-1)-th line H2-3 may include the same material as a first connection electrode CNE1 described in FIG. 6.

The (2-1)-th line H2-3 may be connected to a fifth transistor T5-2 included in the second pixels PX2 through a third contact hole CNT3 penetrating first to fifth insulating layers INS1 to INS5. The fifth transistor T5-2 may correspond to the fifth transistor T5 described in FIG. 5b.

According to one embodiment, the (2-1)-th line H2-3 may intersect the (2-2)-th line V2-4 in the second active area DP-AA2, and may be disposed on a different layer from the (2-2)-th line V2-4.

The (2-2)-th line V2-4 may be disposed on the sixth insulating layer INS6 and may be covered by a seventh insulating layer INS7. The (2-2)-th line V2-4 may include the same material as a second connection electrode CNE2 described in FIG. 6. The (2-2)-th line V2-4 may be connected to the (2-1)-th line H2-3 through a fourth contact hole CNT4 penetrating the sixth insulating layer INS6. The (2-2)-th power line PL2-2 may include a plurality of lines disposed on different layers and connected through contact holes, thereby reducing resistance in the second active area DP-AA2.

According to some example embodiments, in a first mode, a voltage may not be supplied to the (2-1)-th power line PL2-1 from the voltage generator VG, and power may be supplied only to the (2-2)-th power line PL2-2. Accordingly, in the first mode, only the second pixels PX2 may be driven, and the first pixels PX1 may be in a completely turned-off state. As described with reference to FIG. 2F, in the first mode, the first pixels PX1 disposed in the first active area F-AAa may be in a completely turned-off state, and the second pixels PX2 disposed in the second active area R-AAa may be driven.

In contrast to inventive concepts, when the first pixels PX1 are driven to display a black state on the screen in the first mode, unintended power may be supplied, and thus, power consumption may increase.

In the second mode, a voltage may not be supplied from the voltage generator VG to the (2-2)-th power line PL2-2, and power may be supplied only to the (2-1)-th power line PL2-1. Accordingly, in the second mode, only the first pixels PX1 may be driven, and the second pixels PX2 may be in a completely turned-off state. As described with reference to FIG. 2F, in the second mode, the second pixels PX2 disposed in the second active area R-AAa may be in a completely turned-off state, and the first pixels PX1 disposed in the first active area F-AAa may be driven.

In contrast to inventive concepts, when the second pixels PX2 are driven to display a black state on the screen in the second mode, unintended power may be supplied, and thus, power consumption may increase.

According to inventive concepts, unintended power consumption may be reduced by completely turning off power supplied to pixels that do not need to be driven according to an operation mode of the electronic device ED or ED-a. Accordingly, an electronic device ED or ED-a with reduced power consumption may be provided.

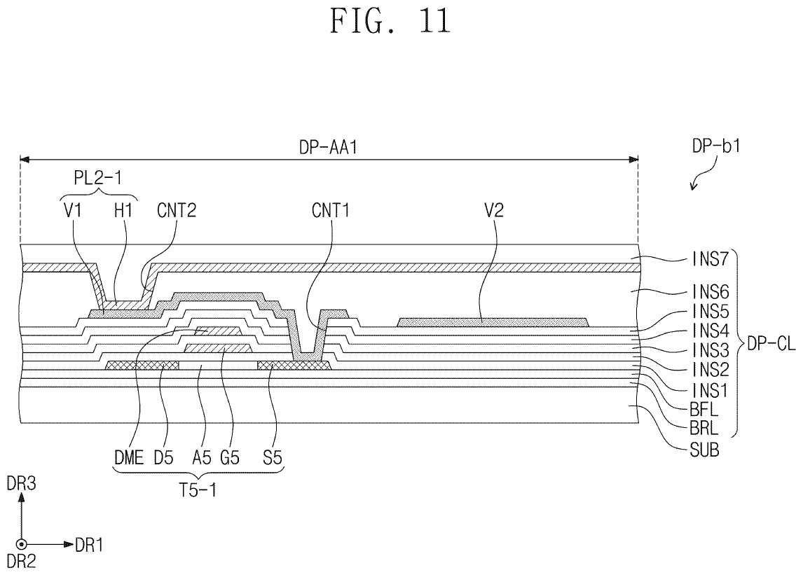

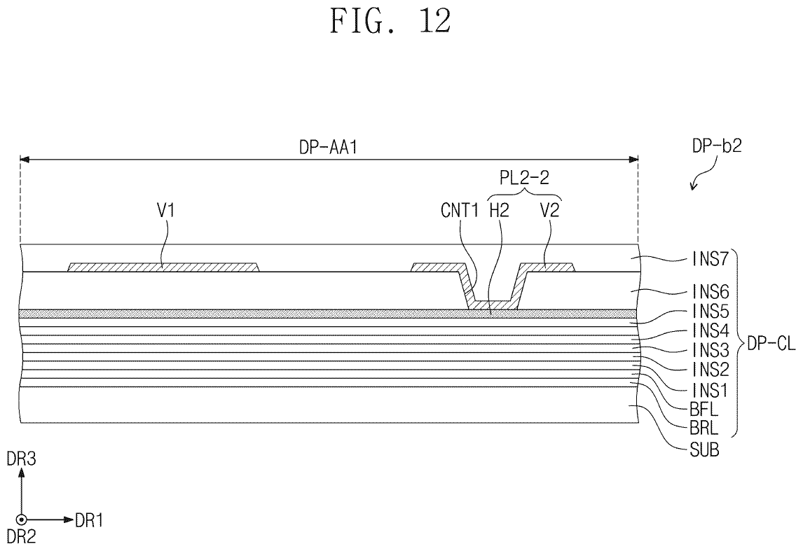

FIGS. 11 and 12 are cross-sectional views of a display panel according to one embodiment. A focus is placed on the differences from the configuration described in FIG. 11A.

Referring to FIG. 11, in a plan view such as FIG. 9, a display panel DP-b1 according to one embodiment may include the (2-1)-th power line PL2-1, which may include the (1-1)-th lines each extending along the first direction DR1 and arranged along the second direction DR2, and the (1-2)-th lines each extending along the second direction DR2 and arranged along the first direction DR1.

The (2-2)-th power line PL2-2 may include the (2-1)-th lines each extending along the first direction DR1 and arranged along the second direction DR2, and the (2-2)-th lines each extending along the second direction DR2 and arranged along the first direction DR1.

According to some example embodiments, the (1-1)-th lines and the (2-1)-th lines, which extend in the horizontal direction based on the display panel DP-b1, may be disposed on an upper layer relative to the (1-2)-th lines and the (2-2)-th lines, which extend in the vertical direction.

FIG. 11 illustrates an example of one of the (1-1)-th lines, namely the (1-1)-th line H1, one of the (1-2)-th lines, namely the (1-2)-th line V1, and one of the (2-2)-th lines, namely the (2-2)-th line V2. The (2-1)-th lines, which extend in the horizontal direction among the (2-2)-th power line PL2-2, may not be disposed in the first active area DP-AA1.

The (1-2)-th line V1 and the (2-2)-th line V2 may be disposed on the fifth insulating layer INS5 and may be covered by the sixth insulating layer INS6. The (1-2)-th line V1 and the (2-2)-th line V2 may be spaced apart from each other on the fifth insulating layer INS5. The (1-2)-th line V1 and the (2-2)-th line V2 may include the same material as the first connection electrode CNE1 described in FIG. 6. The (2-2)-th line V2 may intersect the (1-1)-th line H1 in the first active area DP-AA1.

The (1-2)-th line V1 may be connected to a fifth transistor T5-1 included in the first pixels PX1 through a first contact hole CNT1 penetrating first to fifth insulating layers INS1 to INS5. The fifth transistor T5-1 may correspond to the fifth transistor T5 described in FIG. 5b.

The (2-2)-th line V2 may be connected to a fifth transistor T5 (see FIG. 5B) included in the second pixels PX2 within the second active area DP-AA2 (see FIG. 9).

For example, unlike the display panel DP-B of FIG. 10A, a display panel DP-b1 according to some example embodiments may have horizontal lines disposed on vertical lines.

Referring to FIG. 12, in a plan view such as FIG. 9, a display panel DP-b2 according to one embodiment may include the (2-1)-th power line PL2-1, which may include the (1-1)-th lines each extending along the first direction DR1 and arranged along the second direction DR2, and the (1-2)-th lines each extending along the second direction DR2 and arranged along the first direction DR1.

The (2-2)-th power line PL2-2 may include the (2-1)-th lines each extending along the first direction DR1 and arranged along the second direction DR2, and the (2-2)-th lines each extending along the second direction DR2 and arranged along the first direction DR1.

According to some example embodiments, a portion of the (2-1)-th lines arranged in the horizontal direction among the (2-2)-th power line PL2-2 may also be disposed in the first active area DP-AA1.

FIG. 12 illustrates an example of one of the (1-2)-th lines, namely the (1-2)-th line V1, one of the (2-1)-th lines, namely the (2-1)-th line H2, and one of the (2-2)-th lines, namely the (2-2)-th line V2.

The (2-2)-th line V2 may be connected to the (2-1)-th line H2 in the first active area DP-AA1 through a contact hole CNT defined in the sixth insulating layer INS6.

According to some example embodiments, the (2-1)-th line H2 is a power line for driving the second pixels PX2 (see FIG. 9) and may be disposed on the second active area DP-AA2 and also in the first active area DP-AA1 to reduce resistance.

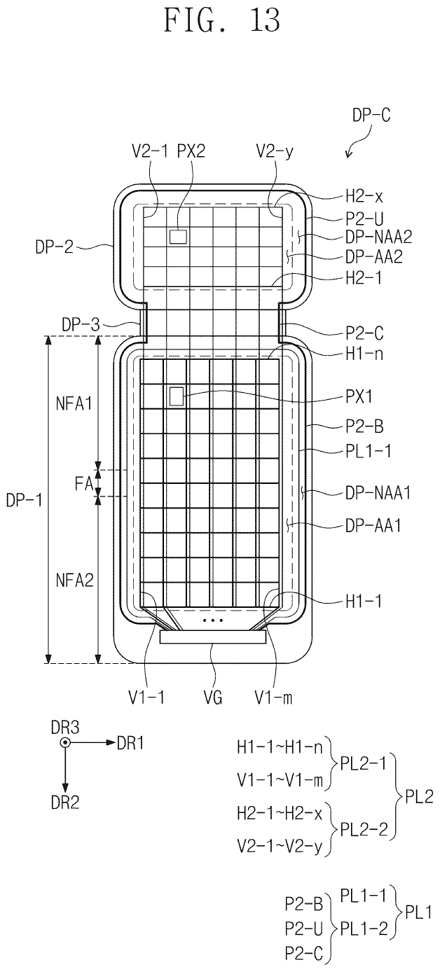

FIG. 13 is a plan view of the display panel according to some example embodiments of inventive concepts. For components that are the same as or similar to those described in FIGS. 7 to 11B, the same or similar reference numerals are used, and redundant descriptions are omitted.

FIG. 13 illustrates a first power line PL1 (see FIGS. 5A and 5B) and a second power line PL2 (see FIGS. 5A and 5B) disposed in a display panel DP-C. A display panel DP-C according to one embodiment may include a first display part DP-1, a second display part DP-2, and a bending part DP-3.

The first display part DP-1 may include a folding area FA and first and second non-folding areas NFA1 and NFA2 spaced apart from each other along a second direction DR2 with the folding area FA therebetween. The folding area FA may be in-folded about a folding axis extending in a first direction DR1.

The first display part DP-1 may include a first active area DP-AA1 and a first peripheral area DP-NAA1 surrounding the first active area DP-AA1. First pixels PX1 may be disposed in the first active area DP-AA1.

A voltage generator VG may be disposed in the first peripheral area DP-NAA1. However, this is merely illustrative, and the voltage generator VG may be disposed outside the display panel DP-A, and a data driver DDV (see FIG. 5A) may be disposed in the first peripheral area DP-NAA1. These configurations are not limited to any particular example embodiment.

The second display part DP-2 may include a second active area DP-AA2 and a second peripheral area DP-NAA2 surrounding the second active area DP-AA2. Second pixels PX2 may be disposed in the second active area DP-AA2. According to some example embodiments, the first pixels PX1 and the second pixels PX2 may be driven independently according to an operation state of the display panel DP-C.

The first power line PL1 and the second power line PL2, as described in FIGS. 5A and 5B, may be disposed on the display panel DP-C. The first power line PL1 may supply a first driving voltage ELVSS (see FIG. 5A) to the first pixels PX1 and the second pixels PX2. The second power line PL2 may supply a second driving voltage ELVDD (see FIG. 5A) to the first pixels PX1 and the second pixels PX2.

The first power line PL1 may include a (1-1)-th power line PL1-1 connected to the first pixels PX1 and the voltage generator VG, and a (1-2)-th power line PL1-2 connected to the second pixels PX2 and the voltage generator VG.

The (1-1)-th power line PL1-1 may be disposed in the first peripheral area DP-NAA1 and may surround the first active area DP-AA1. The (1-1)-th power line PL1-1 may be disposed relatively closer to the first active area DP-AA1 than the (1-2)-th power line PL1-2. The (1-1)-th power line PL1-1 may be connected to a second electrode CE (see FIG. 6) commonly disposed in the first pixels PX1 in the first peripheral area DP-NAA1.

The (1-2)-th power line PL1-2 may include a first line P2-B disposed in the first peripheral area DP-NAA1, a second line P2-C disposed in the bending part DP-3, and a third line P2-U disposed in the second peripheral area DP-NAA2.

One portion of the first line P2-B may be disposed on one side of the first peripheral area DP-NAA1, and another portion of the first line P2-B may be disposed on the other side thereof. The third line P2-U may surround at least a portion of the second peripheral area DP-NAA2. The second line P2-C may connect the first line P2-B and the third line P2-U, which are spaced apart with the bending part DP-3 therebetween.

Accordingly, the second line P2-C may be stored in the housing HAU (see FIG. 3A) in a bent shape corresponding to the bent shape of the bending part DP-3. The third line P2-U may be connected to a second electrode CE (see FIG. 6) commonly disposed in the second pixels PX2 in the second peripheral area DP-NAA2.

The second power line PL2 may include a (2-1)-th power line PL2-1 connected to the voltage generator VG and the first pixel PX1, and a (2-2)-th power line PL2-2 connected to the voltage generator VG and the second pixels PX2.

The (2-1)-th power line PL2-1 may include a plurality of (1-1)-th lines H1-1 to H1-n (where ‘n’ is a natural number greater than 0), each extending along a first direction DR1 and arranged along a second direction DR2, and a plurality of (1-2)-th lines V1-1 to V1-m (where ‘m’ is a natural number greater than 0), each extending along the second direction DR2 and arranged along the first direction DR1.

The (1-1)-th lines H1-1 to H1-n and the (1-2)-th lines V1-1 to V1-m may intersect each other within the first active area DP-AA1. The (1-1)-th lines H1-1 to H1-n and the (1-2)-th lines V1-1 to V1-m may overlap with the emission area PXA and the non-emission area NPXA as described in FIG. 6.

The (1-1)-th lines H1-1 to H1-n may be disposed in the first active area DP-AA1. The (1-2)-th lines V1-1 to V1-m may be connected to the voltage generator VG, and may be disposed in the first active area DP-AA1 through the first peripheral area DP-NAA1 from the voltage generator VG.

The (2-2)-th power line PL2-2 may include a plurality of (2-1)-th lines H2-1 to H2-x (where ‘x’ is a natural number greater than 0), each extending along a first direction DR1 and arranged along a second direction DR2, and a plurality of (2-2)-th lines V2-1 to V2-y (where ‘y’ is a natural number greater than 0), each extending along the second direction DR2 and arranged along the first direction DR1.

The (2-1)-th lines H2-1 to H2-x and the (2-2)-th lines V2-1 to V2-y may intersect each other within the second active area DP-AA2. The (2-1)-th lines H2-1 to H2-x and the (2-2)-th lines V2-1 to V2-y may overlap with the emission area PXA and the non-emission area NPXA as described in FIG. 6.

The (2-1)-th lines H2-1 to H2-x may be disposed only in the second active area DP-AA2. The (2-2)-th lines V2-1 to V2-y may be connected to the voltage generator VG, and may be disposed in the second active area DP-AA2 through the first peripheral area DP-NAA1, the first active area DP-AA1, a bending part DP-3, and the second peripheral area DP-NAA2 from the voltage generator VG.

Each of the (2-2)-th lines V2-1 to V2-y disposed in the first active area DP-AA1 may be disposed adjacent to the corresponding (1-2)-th line V1-1 to V1-m, and may intersect the (1-1)-th lines H1-1 to H1-n.

According to some example embodiments, in a first mode, a voltage may not be supplied to the (1-1)-th power line PL1-1 and the (2-1)-th power line PL2-1 from the voltage generator VG, and power may be supplied only to the (1-2)-th power line PL1-2 and the (2-2)-th power line PL2-2. Accordingly, in the first mode, only the second pixels PX2 may be driven, and the first pixels PX1 may be in a completely turned-off state. As described with reference to FIG. 2F, in the first mode, the first pixels PX1 disposed in the first active area F-AAa may be in a completely turned-off state, and the second pixels PX2 disposed in the second active area R-AAa may be driven.

In contrast to inventive concepts, when the first pixels PX1 are driven to display a black state on the screen in the first mode, unintended power may be supplied, and thus, power consumption may increase.

Alternatively or additionally, in a second mode, a voltage may not be supplied to the (1-2)-th power line PL1-2 and the (2-2)-th power line PL2-2 from the voltage generator VG, and power may be supplied only to the (1-1)-th power line PL1-1 and the (2-1)-th power line PL2-1. Accordingly, in the second mode, only the first pixels PX1 may be driven, and the second pixels PX2 may be in a completely turned-off state. As described with reference to FIG. 2F, in the second mode, the second pixels PX2 disposed in the second active area R-AAa may be in a completely turned-off state, and the first pixels PX1 disposed in the first active area F-AAa may be driven.

In contrast to inventive concepts, when the second pixels PX2 are driven to display a black state on the screen in the second mode, unintended power may be supplied, and thus, power consumption may increase.

According to inventive concepts, unintended power consumption may be reduced by completely turning off power supplied to pixels that do not need to be driven according to an operation mode of the electronic device ED or ED-a. Accordingly, an electronic device ED or ED-a with reduced power consumption may be provided.

According to some example embodiments of inventive concepts, the panel that may display the image to the outside in the folded state of the electronic device and the panel that may display the image in the unfolded state may be connected to different power lines, so that the pixels disposed in one of the panels may be completely turned off during the folding or unfolding operation, whereby the electronic device with reduced unintended power consumption may be provided.

Although some example embodiments have been described, it is understood that inventive concepts should not be limited to these embodiments but various changes and modifications can be made by one of ordinary skill in the art within the spirit and scope of the present invention as hereinafter claimed. Additionally, example embodiments are not necessarily mutually exclusive with one another. For example, some example embodiments may include one or more features described with reference to one or more figures, and may also include one or mor other features described with reference to one or more other figures.

What is claimed is:

1. An electronic device comprising:
a processor configured to provide image data and a display brightness value;
a display panel comprising:
a first display part comprising a folding area configured to fold about a folding axis and non-folding areas spaced apart from each other with the folding area therebetween;
a second display part spaced apart from the first display part; and
a bending part configured to connect the first display part to the second display part and configured to bend about a bending axis so that a rear surface of the second display part faces a rear surface of the first display part;
a panel driver configured to receive the image data and the display brightness value and to drive the display panel based on the image data and the display brightness value; and
a housing configured to accommodate the display panel and the panel driver,
wherein the first display part comprises a first active area and a first peripheral area surrounding the first active area, the second display part comprises a second active area and a second peripheral area surrounding the second active area, and
wherein the display panel comprises:
a base layer;
first pixels on the first active area;
second pixels on the second active area;
a (1-1)-th power line on the first peripheral area and connected to the first pixels; and
a (1-2)-th power line on the first peripheral area, the bending part, and the second peripheral area and connected to the second pixels.

2. The electronic device of claim 1, wherein the (1-1)-th power line is relatively closer to the first active area than the (1-2)-th power line.

3. The electronic device of claim 1, wherein each of the (1-1)-th power line and the (1-2)-th power line comprises a first conductive layer and a second conductive layer on the first conductive layer and in contact with the first conductive layer.

4. The electronic device of claim 1, wherein
the display panel further comprises an encapsulation layer covering the first pixels and the second pixels, and
the encapsulation layer comprises a first inorganic layer, a second inorganic layer on the first inorganic layer, and an organic layer between the first and second inorganic layers.

5. The electronic device of claim 4, further comprising:
at least one dam part defining a boundary of the organic layer on the first and second peripheral areas,
wherein the at least one dam part comprises sequentially laminated dam patterns, each of which comprises an organic material.

6. The electronic device of claim 5, wherein the (1-1)-th power line and the (1-2)-th power line are spaced apart from each other with the at least one dam part therebetween on the first peripheral area.

7. The electronic device of claim 1, wherein the (1-1)-th power line and the (1-2)-th power line are on different layers, respectively.

8. The electronic device of claim 1, wherein the display panel comprises:
a (2-1)-th power line comprising (1-1)-th lines on the first active area, each of which extends in a first direction and arranged in a second direction crossing the first direction, and (1-2)-th lines each of which extends in the second direction and arranged in the first direction; and
a (2-2)-th power line comprising (2-1)-th lines on the second active area, each of which extends in the first direction and arranged in the second direction, and (2-2)-th lines each of which extends in the second direction arranged in the first direction, and
the display panel further comprises a voltage generator configured to individually supply power to the (1-1)-th power line, the (1-2)-th power line, the (2-1)-th power line, and the (2-2)-th power line.

9. The electronic device of claim 8, wherein the (1-2)-th lines are connected to the voltage generator and extend from the voltage generator to the first active area through the first peripheral area.

10. The electronic device of claim 8, wherein the (2-2)-th lines are connected to the voltage generator and extend from the voltage generator to the second active area through the first peripheral area, the first active area, the bending part, and the second peripheral area.

11. The electronic device of claim 8, wherein each of the (2-2)-th lines is between adjacent (1-2)-th lines along the second direction within the first active area, and the (2-2)-th lines do not overlap the (1-2)-th lines.

12. The electronic device of claim 11, wherein each of the (2-2)-th lines intersects the (1-1)-th lines within the first active area.

13. The electronic device of claim 11, wherein
the (1-2)-th lines are on the (1-1)-th lines,
the (2-2)-th lines are between the (2-1)-th lines,
the (1-1)-th lines and the (2-1)-th lines are on the same layer, and
the (1-2)-th lines and the (2-2)-th lines are on the same layer.

14. The electronic device of claim 8, wherein the (1-1)-th lines are disposed on the (1-2)-th lines,
the (2-1)-th lines are between the (2-2)-th lines,
the (1-1)-th lines are on the same layer as the (2-1)-th lines, and
the (1-2)-th lines are on the same layer as the (2-2)-th lines.

15. The electronic device of claim 8, wherein
the (2-2)-th power line further comprises sub-lines which are on the first active area and arranged in the first direction, and each of which extends in the second direction, and
the sub-lines are on the same layer as the (1-1)-th lines.

16. The electronic device of claim 15, wherein the sub-lines intersect the (1-2)-th lines and the (2-2)-th lines and are spaced apart from the (1-1)-th lines.

17. The electronic device of claim 8, wherein
each of the (1-1)-th lines is connected to at least one transistor in the first pixels within the first active area, and
each of the (2-1)-th lines is connected to at least one transistor in the second pixels within the second active area.

18. The electronic device of claim 8, wherein
the (1-1)-th power line is configured to apply a first voltage lower than that of the (2-1)-th power line to the first pixels, and
the (2-1)-th power line is configured to apply a second voltage lower than that of the (2-2)-th power line to the second pixels.

19. The electronic device of claim 8, wherein,
in a first mode in which the folding area is folded, the voltage generator is configured to supply power only to the (1-2)-th and (2-2)-th power lines so as to drive the first pixels, and
in a second mode in which the folding area is unfolded, the voltage generator is configured to supply power only to the (1-1)-th and (2-1)-th power lines so as to drive the second pixels.

20. The electronic device of claim 19, wherein, in the first mode, the first active area overlapping the non-folding areas is in-folded to face each other.
